(19) United States
(12) Patent Application Publication
(10) Pub. No.: US 2022/0277938 A1
(43) Pub. Date: Sep. 1, 2022

(54) SUBSTRATE PROCESSING APPARATUS, PLASMA GENERATING DEVICE, METHOD OF MANUFACTURING SEMICONDUCTOR DEVICE, AND SUBSTRATE PROCESSING METHOD

(71) Applicant: KOKUSAI ELECTRIC CORPORATION, Tokyo (JP)

(72) Inventors: Tomoki IMAMURA, Toyama-shi (JP); Kazuyuki OKUDA, Toyama-shi (JP); Tsuyoshi TAKEDA, Toyama-shi (JP); Daisuke HARA, Toyama-shi (JP)

(73) Assignee: KOKUSAI ELECTRIC CORPORATION, Tokyo (JP)

(21) Appl. No.: 17/560,684

(22) Filed: Dec. 23, 2021

(30) Foreign Application Priority Data
Feb. 26, 2021 (JP) 2021-030785

(51) Int. Cl. H01J 37/32; H01L 21/263

(52) U.S. Cl. CPC H01J 37/32568; H01L 21/263; H01J 37/32174; H01J 2237/327

(57) ABSTRACT

There is provided a technique that includes a process chamber configured to process a substrate; a gas supplier configured to supply a gas into the process chamber; a first plasma electrode unit including a first reference electrode applied with a reference potential and at least one selected from the group of a first application electrode and a second application electrode applied with high-frequency power, the first plasma electrode unit configured to plasma-excite the gas; and a second plasma electrode unit including a second reference electrode applied with a reference potential and a third application electrode applied with high-frequency power, the third application electrode having a length different from a length of the first application electrode or the second application electrode, and the second plasma electrode unit configured to plasma-excite the gas.

### CROSS-REFERENCE TO RELATED APPLICATION(S)

This application is based upon and claims the benefit of priority from Japanese Patent Application No. 2021-030785, filed on Feb. 26, 2021, the entire contents of which are incorporated herein by reference.

### TECHNICAL FIELD

The present disclosure relates to a substrate processing apparatus, a plasma generating device, a method of manufacturing a semiconductor device, and a substrate processing method.

### BACKGROUND

As a process of manufacturing a semiconductor device, there is performed a substrate-processing process in which a precursor gas, a reaction gas, and the like are activated by plasma and supplied to a substrate accommodated in a process chamber of a substrate processing apparatus to form various films such as an insulating film, a semiconductor film, a conductor film, and the like on the substrate or remove various films on the substrate.

### SUMMARY

When processing a plurality of substrates via the use of plasma, it is desirable that the active species generated by plasma are evenly supplied to the respective substrates in order to reduce variations in processing amount for the substrates. If there is a bias in the plasma in the process chamber, a bias in the active species may occur so that the processing amount may differ between the substrates.

Some embodiments of the present disclosure provide a technique capable of reducing variations in processing amount for a plurality of substrates.

According to one or more embodiments of the present disclosure, there is provided a technique that includes a process chamber configured to process a substrate; a gas supplier configured to supply a gas into the process chamber; a first plasma electrode unit including a first reference electrode applied with a reference potential and at least one selected from the group of a first application electrode and a second application electrode applied with high-frequency power, the first plasma electrode unit configured to plasma-excite the gas; and a second plasma electrode unit including a second reference electrode applied with a reference potential and a third application electrode applied with high-frequency power, the third application electrode having a length different from a length of the first application electrode or the second application electrode, and the second plasma electrode unit configured to plasma-excite the gas.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus preferably used in one or more embodiments of the present disclosure, in which the portion of the process furnace is shown in a vertical cross section.

FIG. 2 is a sectional view taken along line A-A in the substrate processing apparatus shown in FIG. 1.

FIG. 3 is an enlarged horizontal sectional view for explaining a buffer structure of the substrate processing apparatus preferably used in the embodiments of the present disclosure.

FIG. 4 is a schematic diagram for explaining a buffer structure of the substrate processing apparatus preferably used in the embodiments of the present disclosure.

FIG. 5 is a simplified explanatory view of a reaction tube and a rod-shaped electrode in a comparative example, and a graph of a power ratio at (substrate stacking direction) positions in a reaction tube (in the process furnace).

FIG. 6 is a simplified explanatory view showing the reaction tube and the lengths of the respective rod-shaped electrodes.

FIG. 7 is a schematic configuration diagram of a controller of the substrate processing apparatus shown in FIG. 1 and is a block diagram which shows an example of a control system of the controller.

FIG. 8 is a flowchart showing an example of a substrate-processing process performed using the substrate processing apparatus shown in FIG. 1.

FIG. 9 is a simplified explanatory view showing the reaction tube and the lengths of the respective rod-shaped electrodes in modification 1 of the vertical process furnace of the substrate processing apparatus preferably used in the embodiments of the present disclosure.

FIG. 10 is a simplified explanatory view showing the reaction tube and the lengths of the respective rod-shaped electrodes in modification 2 of the vertical process furnace of the substrate processing apparatus preferably used in the embodiments of the present disclosure.

FIG. 11 is a simplified explanatory view showing the reaction tube and the lengths of the respective rod-shaped electrodes in modification 3 of the vertical process furnace of the substrate processing apparatus preferably used in the embodiments of the present disclosure.

FIG. 12 is a simplified explanatory view showing the reaction tube and the lengths of the respective rod-shaped electrodes in modification 4 of the vertical process furnace of the substrate processing apparatus preferably used in the embodiments of the present disclosure.

FIG. 13 is a simplified explanatory view showing the reaction tube and the lengths of the respective rod-shaped electrodes in modification 5 of the vertical process furnace of the substrate processing apparatus preferably used in the embodiments of the present disclosure.

FIG. 14 is a simplified explanatory view showing the reaction tube and the lengths of the respective rod-shaped electrodes in modification 6 of the vertical process furnace of the substrate processing apparatus preferably used in the embodiments of the present disclosure.

FIG. 15 is a schematic horizontal sectional view for explaining modification 7 of the vertical process furnace of the substrate processing apparatus preferably used in the embodiments of the present disclosure.

FIG. 16 is a schematic horizontal sectional view for explaining modification 8 of the vertical process furnace of the substrate processing apparatus preferably used in the embodiments of the present disclosure.

FIG. 17 is a schematic horizontal sectional view for explaining modification 9 of the vertical process furnace of the substrate processing apparatus preferably used in the embodiments of the present disclosure.

FIG. 18 is a schematic horizontal sectional view for explaining modification 10 of the vertical process furnace of the substrate processing apparatus preferably used in the embodiments of the present disclosure.

FIG. 19 is a schematic horizontal sectional view for explaining modification 11 of the vertical process furnace of the substrate processing apparatus preferably used in the embodiments of the present disclosure.

FIG. 20 is a schematic horizontal sectional view for explaining modification 12 of the vertical process furnace of the substrate processing apparatus preferably used in the embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

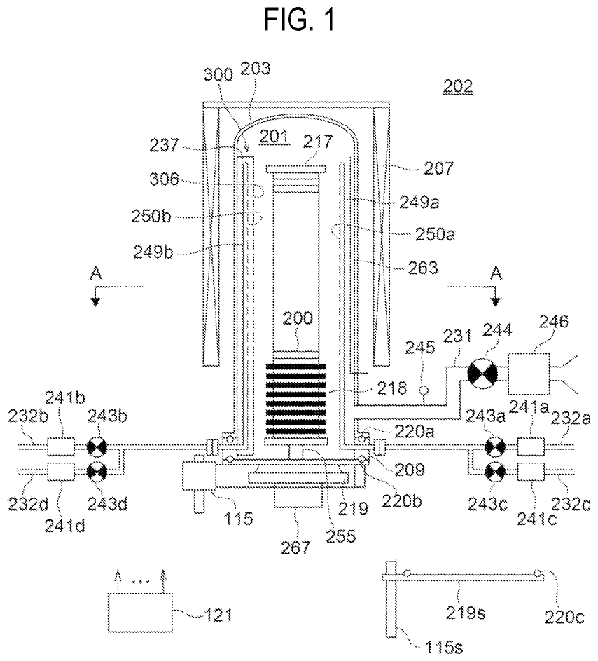

Hereinafter, one or more embodiments of the present disclosure will be described with reference to FIGS. 1 to 8. The drawings used in the following description are schematic. The dimensional relationship of each element shown in the drawings, the ratio of each element, and the like do not always match the actual ones. Further, even between the drawings, the dimensional relationship of each element, the ratio of each element, and the like do not always match.

### (1) Configuration of Substrate Processing Apparatus

### (Heating Device)

As shown in FIG. 1, a process furnace 202 includes a heater 207 as a heating device (heating mechanism). The heater 207 has a cylindrical shape and is vertically installed by being supported by a heater base (not shown) as a holding plate. The heater 207 also functions as an activation mechanism (excitation part) that activates (excites) a gas with heat as described below.

### (Process Chamber)

Inside the heater 207, a reaction tube 203 is arranged concentrically with the heater 207. The reaction tube 203 is made of a heat-resistant material such as, for example, quartz (SiO₂) or silicon carbide (SiC) and is formed in a cylindrical shape with an upper end thereof closed and a lower end thereof opened. Below the reaction tube 203, a manifold 209 is arranged concentrically with the reaction tube 203. The manifold 209 is made of a metal such as stainless steel (SUS) or the like and is formed in a cylindrical shape with upper and lower ends thereof opened. The upper end of the manifold 209 is engaged with the lower end of the reaction tube 203 and is configured to support the reaction tube 203. An O-ring 220a as a seal member is installed between the manifold 209 and the reaction tube 203. As the manifold 209 is supported by the heater base, the reaction tube 203 comes into a vertically installed state. A process container (reaction container) mainly includes the reaction tube 203 and the manifold 209.

A process chamber 201 is formed in the hollow portion of the process container. The process chamber 201 is configured to accommodate a plurality of wafers 200 as substrates. The process container is not limited to the above configuration, and the reaction tube 203 may be referred to as a process container.

### (Gas Supply Part)

Nozzles 249a and 249b are installed in the process chamber 201 so as to penetrate the side wall of the manifold 209. Gas supply pipes 232a and 232b are connected to the nozzles 249a and 249b, respectively. As described above, the process container is installed with two nozzles 249a and 249b and two gas supply pipes 232a and 232b, so that a plurality of types of gas can be supplied into the process chamber 201. When the reaction tube 203 is used as the process container, the nozzles 249a and 249b may be installed so as to penetrate the side wall of the reaction tube 203.

Mass flow controllers (WC) 241a and 241b as flow rate controllers (flow rate control parts) and valves 243a and 243b as opening/closing valves are installed in the gas supply pipes 232a and 232b, respectively, sequentially from the upstream side. Gas supply pipes 232c and 232d for supplying an inert gas are connected to the gas supply pipes 232a and 232b, respectively, on the downstream side of the valves 243a and 243b. MFCs 241c and 241d and valves 243c and 243d are respectively installed in the gas supply pipes 232c and 232d, respectively, sequentially from the upstream side.

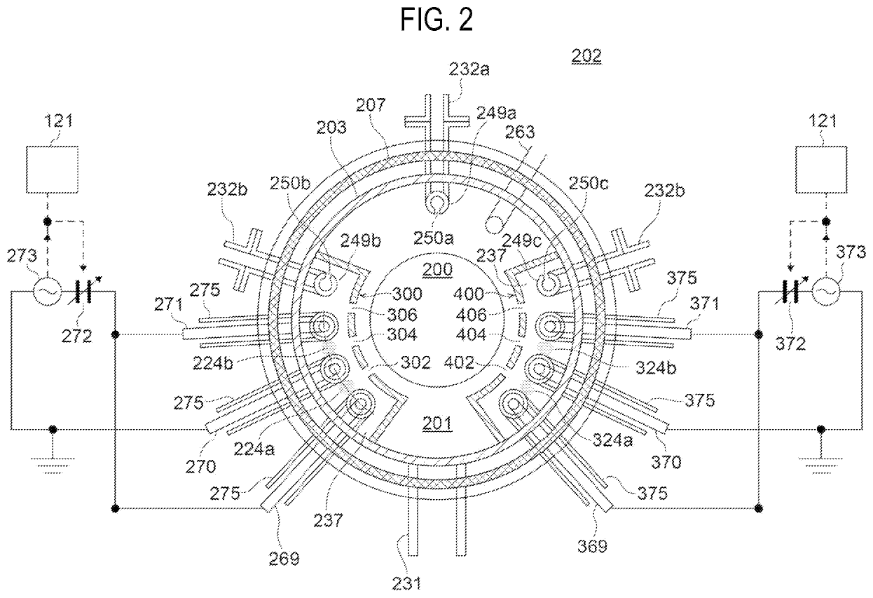

As shown in FIG. 2, the nozzle 249a is installed to extend upward in the stacking direction of the wafers 200 from the lower portion to the upper portion of the inner wall of the reaction tube 203 in a space between the inner wall of the reaction tube 203 and the wafers 200. That is, the nozzle 249a is installed on the lateral side of the wafer arrangement region (mounting region) in which the wafers 200 are arranged (mounted) and in the region horizontally surrounding the wafer arrangement region, so as to extend along the wafer arrangement region. That is, the nozzle 249a is installed on the lateral side of the end portion (peripheral edge portion) of each of the wafers 200 loaded into the process chamber 201 in a direction perpendicular to the surfaces (flat surfaces) of the wafers 200.

Gas supply holes 250a for supplying a gas are installed on the side surface of the nozzle 249a. The gas supply holes 250a are opened so as to face the center of the reaction tube 203 and are capable of supplying a gas toward the wafers 200. The gas supply holes 250a are arranged from the lower portion to the upper portion of the reaction tube 203 and are installed at the same opening area and at the same opening pitch.

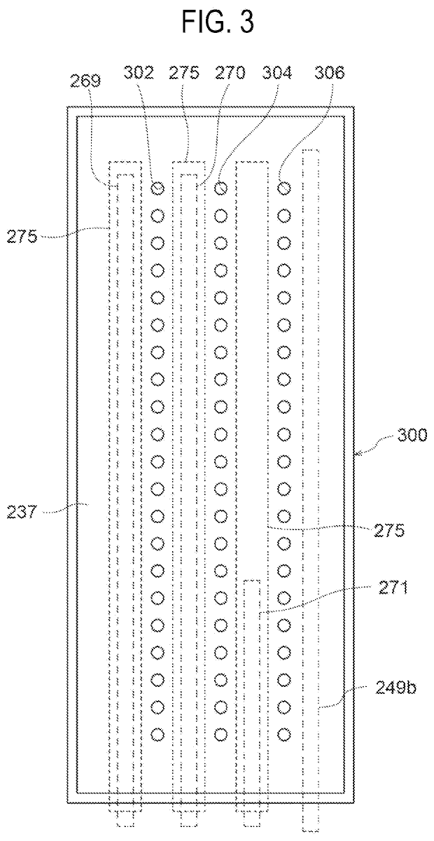

A nozzle 249b is connected to the tip of the gas supply pipe 232b. The nozzle 249b is installed in a buffer chamber 237, which is a gas dispersion space. As shown in FIG. 2, the buffer chamber 237 is installed along the stacking direction of the wafers 200 in a space having an annular shape when viewed in a plane view between the inner wall of the reaction tube 203 and the wafers 200 and in a region extending from the lower portion to the upper portion of the inner wall of the reaction tube 203. That is, a part of the buffer chamber 237 is formed by a buffer structure (partition wall) 300 so as to extend along the wafer arrangement region in a region horizontally surrounding the wafer arrangement region on the lateral side of the wafer arrangement region. In the buffer chamber 237, the space in the reaction tube 203 partitioned by the buffer structure 300 is referred to as a second buffer chamber. The buffer structure 300 is made of an insulating material which is a heat-resistant material such as quartz or SiC. Gas supply ports 302, 304, and 306 for supplying gases are formed on the arc-shaped wall surface of the buffer structure 300. As shown in FIGS. 2 and 3, the gas supply ports 302, 304, and 306 are opened toward the center of the reaction tube 203 at the positions of the opposite wall surface in a plasma generation region 224a between the rod-shaped electrodes 269 and 270, a plasma generation region 224b between the rod-shaped electrodes 270 and 271, and a region between the rod-shaped electrode 271 and the nozzle 249b and are capable of supplying gases toward the wafers 200. The gas supply ports 302, 304, and 306 are installed from the lower portion to the upper portion of the reaction tube 203 and are installed at the same opening area and at the same opening pitch.

The nozzle 249b is installed so as to extend upward in the stacking direction of the wafers 200 from the lower portion to the upper portion of the inner wall of the reaction tube 203. That is, the nozzle 249b is installed inside the buffer structure 300 on the lateral side of the wafer arrangement region in which the wafers 200 are arranged and in the region horizontally surrounding the wafer arrangement region, so as to extend along the wafer arrangement region. That is, the nozzle 249b is installed on the lateral side of the end portion of each of the wafers 200 loaded into the process chamber 201 in a direction perpendicular to the surfaces of the wafers 200. Gas supply holes 250b for supplying a gas are installed on the side surface of the nozzle 249b. The gas supply holes 250b are opened so as to face the wall surface formed in the radial direction with respect to the arc-shaped wall surface of the buffer structure 300 and are capable of supplying a gas toward the wall surface. As a result, the reaction gas is dispersed in the buffer chamber 237 and is not directly sprayed on the rod-shaped electrodes 269 to 271, whereby the generation of particles is suppressed. In a similar manner as the gas supply holes 250a, the gas supply holes 250b are installed from the lower portion to the upper portion of the reaction tube 203.

A buffer structure 400 having the same structure as the buffer structure 300 is installed on the inner wall of the reaction tube 203. That is, the other part of the buffer chamber 237 is formed by the buffer structure 400 to extend along the wafer arrangement region in the region horizontally surrounding the wafer arrangement region on the lateral side of the wafer arrangement region. In the buffer chamber 237, the space in the reaction tube 203 partitioned by the buffer structure 400 is referred to as a first buffer chamber. As shown in FIG. 2, in a plane view, the buffer structure 300 and the buffer structure 400 are installed line-symmetrically with respect to a straight line passing through the exhaust pipe 231 (described below) and the center of the reaction tube 203 with the exhaust pipe 231 interposed therebetween. Further, in a plane view, the nozzle 249a is installed at a position facing the exhaust pipe 231 across the wafers 200. In addition, the nozzle 249b and the nozzle 249c are installed at positions far from the exhaust pipe 231 in the buffer chambers 237 of the buffer structures 300 and 400, respectively.

The gas supply pipe 232b is branched into two portions. The nozzle 249b described above is connected to the tip of one portion of the gas supply pipe 232b, and the nozzle 249c is connected to the tip of the other portion of the gas supply pipe 232b. The nozzle 249c is installed in the buffer chamber 237 on the buffer structure 400 side, which is a gas dispersion space. In FIG. 1, the buffer structure 400 is overlapped with the buffer structure 300 and is not shown.

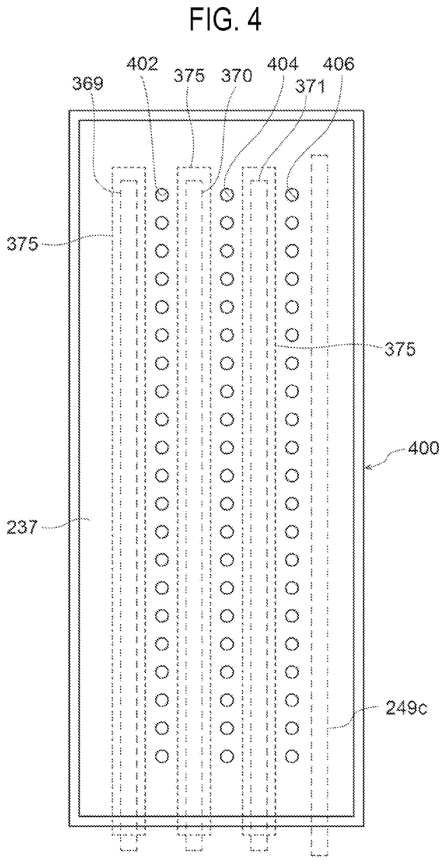

Gas supply ports 402, 404, and 406 for supplying gases are formed on the arc-shaped wall surface of the buffer structure 400. As shown in FIGS. 2 and 4, the gas supply ports 402, 404, and 406 are opened toward the center of the reaction tube 203 at the positions of the opposite wall surface in a plasma generation region 324a between the rod-shaped electrodes 369 and 370, a plasma generation region 324b between the rod-shaped electrodes 370 and 371, and a region between the rod-shaped electrode 371 and the nozzle 249c and are capable of supplying gases toward the wafers 200. The gas supply ports 402, 404, and 406 are arranged from the lower portion to the upper portion of the reaction tube 203 and are installed at the same opening area and at the same opening pitch.

The nozzle 249c is installed so as to extend upward in the stacking direction of the wafers 200 from the lower portion to the upper portion of the inner wall of the reaction tube 203. That is, the nozzle 249c is installed inside the buffer structure 400 on the lateral side of the wafer arrangement region in which the wafers 200 are arranged and in the region horizontally surrounding the wafer arrangement region, so as to extend along the wafer arrangement region. That is, the nozzle 249c is installed on the lateral side of the end portion of each of the wafers 200 loaded into the process chamber 201 in a direction perpendicular to the surfaces of the wafers 200. Gas supply holes 250c for supplying a gas are installed on the side surface of the nozzle 249c. The gas supply holes 250c are opened so as to face the wall surface formed in the radial direction with respect to the arc-shaped wall surface of the buffer structure 400 and are capable of supplying a gas toward the wall surface. As a result, the reaction gas is dispersed in the buffer chamber 237 and is not directly sprayed on the rod-shaped electrodes 369 to 371, whereby the generation of particles is suppressed. In a similar manner as the gas supply holes 250a, the gas supply holes 250c are installed from the lower portion to the upper portion of the reaction tube 203.

As described above, in the present embodiments, the gases are conveyed via the nozzles 249a, 249b, and 249c and two buffer chambers 237 arranged in the vertically elongated space having an annular shape when viewed in a plane view, i.e., the cylindrical space, defined by the inner surface of the side wall of the reaction tube 203 and the end portions of the plurality of wafers 200 arranged in the reaction tube 203. Then, the gases are first discharged in the vicinity of the wafers 200 into the space in the reaction tube 203, in which the wafers 200 are arranged, from the gas supply holes 250a, 250b, and 250c and the gas supply ports 302, 304, 306, 402, 404, and 406 respectively opened in the nozzles 249a, 249b, and 249c and the two buffer chambers 237. The main flow of gas in the reaction tube 203 is in a direction parallel to the surfaces of the wafers 200, i.e., in a horizontal direction. With such a configuration, the gas can be uniformly supplied to each of the wafers 200, and the uniformity of the film thickness of the film formed on each of the wafers 200 can be improved. The gas flowing on the surfaces of the wafers 200, i.e., the residual gas left after reaction, flows toward the exhaust port, i.e., the exhaust pipe 231 described below. However, the direction of the flow of the residual gas is appropriately specified depending on the position of the exhaust port and is not limited to the vertical direction.

From the gas supply pipe 232a, a precursor containing a predetermined element, for example, a precursor gas containing silicon (Si) as a predetermined element is supplied into the process chamber 201 via the MFC 241a, the valve 243a, and the nozzle 249a.

The precursor gas is a precursor in a gaseous state, for example, a gas obtained by vaporizing a precursor staying in a liquid state under the room temperature and the atmospheric pressure, a precursor staying in a gaseous state under the room temperature and the atmospheric pressure, and the like. When the term “precursor” is used herein, it means a “liquid precursor in a liquid state”, a “precursor gas in a gaseous state”, or both. The precursor gas can be a raw material gas or a source gas.

From the gas supply pipe 232b, a reaction gas (reactant) having a chemical structure different from that of the precursor, for example, an oxygen (O)-containing gas is supplied into the process chamber 201 via the MFC 241b, the valve 243b, and the nozzles 249b and 249c. The O-containing gas acts as an oxidizing agent (oxidizing gas), i.e., as an O source. For example, this gas is plasma-excited by using a plasma source described below and is supplied as an excited gas.

From the gas supply pipes 232c and 232d, an inert gas is supplied into the process chamber 201 via the MFCs 241c and 241d, the valves 243c and 243d, and the nozzles 249a, 249b, and 249c, respectively.

A precursor gas supply system as a first gas supply system mainly includes the gas supply pipe 232a, the MFC 241a, and the valve 243a. A reaction gas supply system (reactant supply system) as a second gas supply system mainly includes the gas supply pipe 232b, the MFC 241b, and valve 243b. An inert gas supply system mainly includes the gas supply pipes 232c and 232d, the MFCs 241c and 241d, and the valves 243c and 243d. The precursor gas supply system, the reaction gas supply system, and the inert gas supply system are also simply referred to as a gas supply system (gas supply part or gas supplier). In the present disclosure, the gases such as the precursor gas and the reaction gas used for substrate processing to the wafers 200 may be collectively referred to as a processing gas. The configurations of the precursor gas supply system, the reaction gas supply system, and the like that supply these gases may be collectively referred to as a processing gas supply system (processing gas supply part or processing gas supplier).

### (Substrate Support)

As shown in FIG. 1, a boat 217 as a substrate support (substrate support part) is configured to support a plurality of wafers 200, for example, 25 to 200 wafers 200 in a horizontal posture and in multiple stages by vertically arranging the wafers 200 with the centers thereof aligned with each other, i.e., arrange the wafers 200 at intervals. The boat 217 is made of a heat-resistant material such as quartz or SiC. At the lower portion of the boat 217, heat-insulating plates 218 made of a heat-resistant material such as quartz or SiC are supported in multiple stages. With this configuration, the heat from the heater 207 is less likely to be transmitted toward the seal cap 219. However, the present embodiments are not limited to such a form. For example, instead of installing the heat-insulating plates 218 at the lower portion of the boat 217, a heat insulating cylinder configured as a tubular member made of a heat-resistant material such as quartz or SiC may be installed.

### (Plasma Generation Part)

Next, a plasma generation part will be described with reference to FIGS. 1 to 6.

As shown in FIG. 2, plasma is generated inside the buffer chamber 237, which is a vacuum partition made of quartz or the like, at the time of supplying the reaction gas, by using a capacitively coupled plasma (abbreviation: CCP).

In one example of the present embodiments, as shown in FIG. 3, three rod-shaped electrodes 269, 270, and 271 composed of a conductor and having an elongated structure are arranged in the buffer chamber 237 of the buffer structure 300 to extend along the stacking direction of the wafers 200 from the lower portion to the upper portion of the reaction tube 203. Each of the rod-shaped electrodes 269, 270, and 271 is installed in parallel with the nozzle 249b. Each of the rod-shaped electrodes 269, 270, and 271 is protected by being covered with an electrode protection tube 275 from the upper portion to the lower portion thereof. The electrode protection tube 275 is composed of a quartz tube that protects each of the rod-shaped electrodes 269, 271, and 270. In the present embodiments, three quartz tubes are individually separated. The electrode protection tube may have another shape, for example, a partition wall shape so that each of the rod-shaped electrodes 269, 270, and 271 does not come into contact with each other. Each of the rod-shaped electrodes 269 and 270 is arranged so that the tip thereof is located at the upper portion of the electrode protection tube 275, and the rod-shaped electrode 271 is arranged so that the tip thereof is located at the lower portion of the electrode protection tube 275. The rod-shaped electrodes 269 and 270 have substantially the same length, and the rod-shaped electrode 271 has a length different from the lengths of the rod-shaped electrodes 269 and 270. More specifically, the length of the rod-shaped electrode 271 is different from the lengths of the rod-shaped electrodes 269 and 270 in the stacking direction of the wafers 200. The rod-shaped electrodes 269 and 270 are longer than the rod-shaped electrode 271.

As shown in FIG. 2, among the rod-shaped electrodes 269, 270, and 271, the rod-shaped electrodes 269 and 271 as application electrodes arranged at both ends (the rod-shaped electrode 269 as a fourth application electrode and the rod-shaped electrode 271 as a third application electrode) are connected to a high-frequency power source 273 via a matcher 272 and is applied with high-frequency power. The rod-shaped electrode 270 as a second reference electrode is connected to the ground as a reference potential and is grounded to receive a reference potential. As a result, the rod-shaped electrodes connected to the high-frequency power source 273 and the grounded rod-shaped electrode are alternately arranged. The rod-shaped electrode 270 arranged between the rod-shaped electrodes 269 and 271 connected to the high-frequency power source 273 is a grounded rod-shaped electrode and is commonly used for the rod-shaped electrodes 269 and 271.

In other words, the grounded rod-shaped electrode 270 is arranged so as to be sandwiched between the rod-shaped electrodes 269 and 271 adjacent thereto and connected to the high-frequency power source 273. The rod-shaped electrodes 269 and 270 and the rod-shaped electrodes 271 and 270 are respectively configured to be paired with each other to generate plasma. That is, the grounded rod-shaped electrode 270 is commonly used for the two rod-shaped electrodes 269 and 271 arranged adjacent to the rod-shaped electrode 270 and connected to the high-frequency power source 273. This makes it possible to reduce the number of reference electrodes. Then, by applying high-frequency (RF) power from the high-frequency power source 273 to the rod-shaped electrodes 269 and 271, plasma is generated in the plasma generation region 224a between the rod-shaped electrodes 269 and 270 and the plasma generation region 224b between the rod-shaped electrodes 270 and 271.

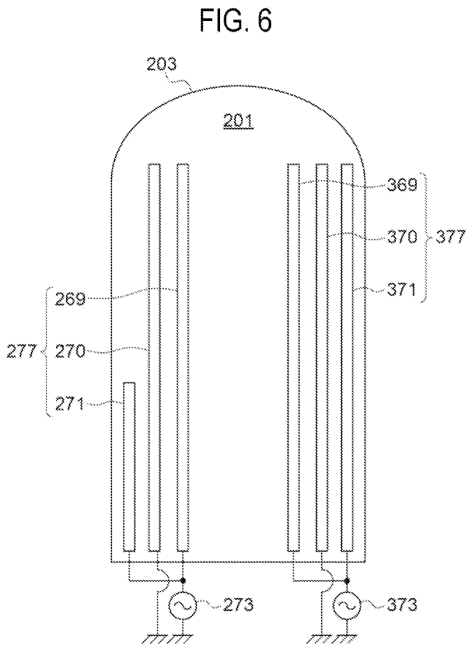

A second plasma electrode unit 277 (see FIG. 6 where the electrode protection tubes 275 are not shown) mainly includes the rod-shaped electrodes 269, 270, and 271 and the electrode protection tubes 275. Although the two rod-shaped electrodes 269 and 271 have been described as examples of the application electrodes, the number of application electrodes may be one or three or more.

As shown in FIG. 4, three rod-shaped electrodes 369, 370, and 371 composed of a conductor and having an elongated structure are arranged in the buffer chamber 237 of the buffer structure 400 to extend along the stacking direction of the wafers 200 from the lower portion to the upper portion of the reaction tube 203. Each of the rod-shaped electrodes 369, 370, and 371 is installed in parallel with the nozzle 249c. Each of the rod-shaped electrodes 369, 370, and 371 is protected by being covered with an electrode protection tube 375 from the upper portion to the lower portion thereof. The electrode protection tube 375 is composed of a quartz tube that protects each of the rod-shaped electrodes 369, 371, and 370. In the present embodiments, three quartz tubes are individually separated. The electrode protection tube may have another shape, for example, a partition wall shape so that each of the rod-shaped electrodes 369, 370, and 371 does not come into contact with each other. Each of the rod-shaped electrodes 369, 370, and 371 is arranged so that the tip thereof is located at the upper portion of the electrode protection tube 375.

The rod-shaped electrodes 369, 370 and 371 have substantially the same length which is substantially the same as the length of the rod-shaped electrodes 269 and 270. The rod-shaped electrodes 369, 370, and 371 have a length different from the length of the rod-shaped electrode 271. More specifically, the length of the rod-shaped electrodes 369, 370 and 371 is different from the length of the rod-shaped electrode 271 in the stacking direction of the wafers 200. The rod-shaped electrodes 369, 370, and 371 are longer than the rod-shaped electrode 271.

As shown in FIG. 2, among the rod-shaped electrodes 369, 370, and 371, the rod-shaped electrodes 369 and 371 as application electrodes arranged at both ends (the rod-shaped electrode 369 as a first application electrode and the rod-shaped electrode 371 as a second application electrode) are connected to a high-frequency power source 373 via a matcher 372 and is applied with high-frequency power. The rod-shaped electrode 370 as a first reference electrode is connected to the ground as a reference potential and is grounded to receive a reference potential. As a result, the rod-shaped electrodes connected to the high-frequency power source 373 and the grounded rod-shaped electrode are alternately arranged. The rod-shaped electrode 370 arranged between the rod-shaped electrodes 369 and 371 connected to the high-frequency power source 373 is a grounded rod-shaped electrode and is commonly used for the rod-shaped electrodes 369 and 371.

In other words, the grounded rod-shaped electrode 370 is arranged so as to be sandwiched between the rod-shaped electrodes 369 and 371 adjacent thereto and connected to the high-frequency power source 373. The rod-shaped electrodes 369 and 370 and the rod-shaped electrodes 371 and 370 are respectively configured to be paired with each other to generate plasma. That is, the grounded rod-shaped electrode 370 is commonly used for the two rod-shaped electrodes 369 and 371 arranged adjacent to the rod-shaped electrode 370 and connected to the high-frequency power source 373. This makes it possible to reduce the number of reference electrodes. Then, by applying high-frequency (RF) power from the high-frequency power source 373 to the rod-shaped electrodes 369 and 371, plasma is generated in the plasma generation region 324a between the rod-shaped electrodes 369 and 370 and the plasma generation region 324b between the rod-shaped electrodes 370 and 371.

A first plasma electrode unit 377 (see FIG. 6 where the electrode protection tubes 375 are not shown) mainly includes the rod-shaped electrodes 369, 370, and 371 and the electrode protection tubes 375. Although the two rod-shaped electrodes 369 and 371 have been described as examples of the application electrodes, the number of application electrodes may be one or three or more.

The first plasma electrode unit 377 and the second plasma electrode unit 277 constitute a plasma generating device as a plasma source. The matchers 272 and 372 and the high-frequency power sources 273 and 373 may be included in the plasma generating device. As will be described below, the plasma generating device functions as a plasma excitation part (activation mechanism) that excites (activates) a gas into a plasma state.

The electrode protection tube 275 has a structure in which each of the rod-shaped electrodes 269, 270, and 271 can be inserted into the buffer chamber 237 in a state of being isolated from the atmosphere in the buffer chamber 237. Further, the electrode protection tube 375 has a structure in which each of the rod-shaped electrodes 369, 370, and 371 can be inserted into the buffer chamber 237 in a state of being isolated from the atmosphere in the buffer chamber 237. If the O₂ concentration inside the electrode protection tubes 275 and 375 is about the same as the O₂ concentration of the outside air (atmosphere), the rod-shaped electrodes 269, 270, and 271 respectively inserted into the electrode protection tubes 275 and the rod-shaped electrodes 369, 370, and 371 respectively inserted into the electrode protection tubes 375 may be oxidized by the heat generated by the heater 207. Therefore, the inside of the electrode protection tubes 275 and 375 is filled with an inert gas such as a N₂ gas or the like, or the inside of the electrode protection tubes 275 and 375 is purged with an inert gas such as a N₂ gas or the like by using an inert gas purge mechanism. This makes it possible to reduce the O₂ concentration inside the electrode protection tubes 275 and 375 and to prevent oxidation of the rod-shaped electrodes 269, 270, 271, 369, 370, and 371.

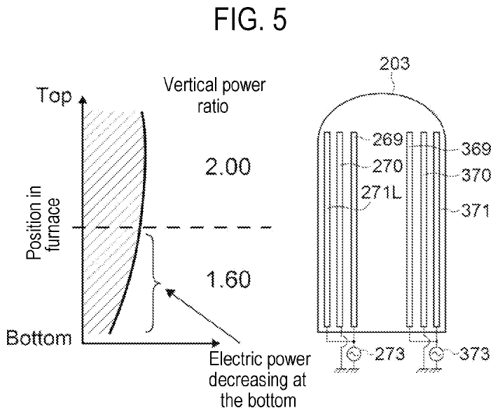

Now, the bias of plasma generation in the reaction tube 203 will be described. FIG. 5 is a simplified explanatory view showing a comparative example in which rod-shaped electrodes 269, 270, 271L, 369, 370, and 371 are arranged in the reaction tube 203. FIG. 5 shows, by hatching, the power ratio at (substrate stacking direction) positions in the reaction tube 203 (in the process furnace). The vertical direction in the graph of FIG. 5 corresponds to the vertical direction (extension direction of the rod-shaped electrodes) of the reaction tube 203 shown on the right side. In FIG. 5, other configurations in the reaction tube 203, such as the electrode protection tubes 275 and 375 and the like, are omitted. The rod-shaped electrode 271L is an application electrode having the length different from the length of the rod-shaped electrode 271 of the present embodiments and having the same length as the rod-shaped electrodes 269, 270, 369, 370, and 371.

The disclosers have found that, as shown in FIG. 5, the power ratio tends to be larger on the tip side (top side) than on one end side (power supply side/bottom side) of the rod-shaped electrode. As an example, when the same voltage is applied from the high-frequency power sources 273 and 373, the power ratio between the upper side and the lower side is 2.0:1.6 in FIG. 5. Therefore, when rod-shaped electrodes of the same length are arranged as shown in FIG. 5, the density of plasma generated on the lower side (power supply side of the rod-shaped electrode) in the reaction tube 203 is smaller than that on the upper side (tip side of the rod-shaped electrode). Fewer active species are generated by plasma excitation on the lower side (power supply side of the rod-shaped electrode) in the reaction tube 203.

Therefore, as shown in FIG. 6, the lengths of the rod-shaped electrodes 269, 270, 369, 370, and 371 in the reaction tube 203 are made substantially equal, and the length of the rod-shaped electrode 271 is made shorter than the lengths of the rod-shaped electrodes 269, 270, 369, 370, and 371. As a result, the density of the plasma generated on the upper side in the reaction tube 203 becomes smaller than that of the case shown in FIG. 5, and the difference in the density of the plasma generated on the upper side and the lower side in the reaction tube 203 (i.e., the bias of distribution of the plasma density) becomes smaller. Accordingly, it is also possible to reduce the bias of the amount of active species generated by plasma excitation in the reaction tube 203 depending on the position in the vertical position.

Further, in the present embodiments, two buffer structures (buffer structures 300 and 400) including the plasma generation part are installed, and the buffer structures 300 and 400 include the high-frequency power sources 273 and 373 and the matchers 272 and 372, respectively. Each of the high-frequency power sources 273 and 373 is connected to the controller 121, which makes it possible to execute plasma control for each buffer chamber 237 of the buffer structures 300 and 400. That is, the controller 121 monitors the impedance of each plasma generation part and independently controls the high-frequency power sources 273 and 373 so that the amount of active species does not become biased in each buffer chamber 237. The controller 121 controls the output of the high-frequency power sources depending on the magnitude of the impedance.

As a result, a sufficient amount of active species can be supplied to the wafers even if the high-frequency power of each plasma generation part is reduced as compared with the case where there is one plasma generation part, whereby the in-plane uniformity of the wafer can be improved. In addition, unlike the case where plasma control for two plasma generation parts is performed by one high-frequency power source, by installing the high-frequency power source for each plasma generation part, it becomes easier to grasp the occurrence of an abnormality such as disconnection or the like in each plasma generation part. Further, since the distance between the high-frequency power source and each electrode can be easily adjusted, the alternating current generated by the difference in the distance between each electrode and the high-frequency power source can easily suppress the difference in power application.

Further, as described above, in the present embodiments, the first plasma electrode unit 377 and the second plasma electrode unit 277 are supplied with electric power from different high-frequency power sources 273 and 373. Therefore, the magnitude of the power supplied from the high-frequency power source 273 as the second high-frequency power source may be made different from the magnitude of the power supplied from the high-frequency power source 373 as the first high-frequency power source in order to make the length of the rod-shaped electrode 271 shorter than the length of the other rod-shaped electrodes 269, 270, 369, 370, and 371 and to reduce the difference in vertical plasma density in the reaction tube 203 (or the bias of the amount of active species depending on the position).

For example, when the power ratio on the lower side (power supply side of the rod-shaped electrode) in the reaction tube 203 becomes larger than the power ratio on the upper side (tip side of the rod-shaped electrode) due to the short length of the rod-shaped electrode 271, the power supplied from the high-frequency power source 273 can be adjusted to be smaller than the power supplied from the high-frequency power source 373. Further, if the power ratio on the lower side (power supply side of the rod-shaped electrode) in the reaction tube 203 is smaller than the power ratio on the upper side (tip side of the rod-shaped electrode) even when the length of the rod-shaped electrode 271 is made short, the power supplied from the high-frequency power source 273 can be adjusted to be larger than the power supplied from the high-frequency power source 373. By controlling the high-frequency power source 373 and the high-frequency power source 273 in this way, the total distribution including a distribution of electric power applied to the first plasma electrode unit 377 and a distribution of electric power applied to the second plasma electrode unit 277 in the extension direction of the first plasma electrode unit 377 and the second plasma electrode unit 277 can be adjusted to be uniform. In other words, by controlling the high-frequency power source 373 and the high-frequency power source 273 in this way, the distribution of the amount of active species generated by plasma exciting the gas by the first plasma electrode unit 377 and the second plasma electrode unit 277 can be adjusted so as to be uniform in the extension direction of the first plasma electrode unit 377 and the second plasma electrode unit 277.

### (Exhaust Part)

As shown in FIG. 1, an exhaust pipe 231 for exhausting the atmosphere in the process chamber 201 is installed in the reaction tube 203. A vacuum pump 246 as an evacuation device is connected to the exhaust pipe 231 via a pressure sensor 245 as a pressure detector (pressure detection part) for detecting the pressure inside the process chamber 201 and an APC (Auto Pressure Controller) valve 244 as an exhaust valve (pressure regulation part). The APC valve 244 is configured so that it can perform or stop vacuum evacuation of the interior of the process chamber 201 by being opened and closed in a state in which the vacuum pump 246 is operated. Furthermore, the APC valve 244 is configured so that it can regulate the pressure inside the process chamber 201 by adjusting the valve opening degree based on the pressure information detected by the pressure sensor 245 in a state in which the vacuum pump 246 is operated. An exhaust system mainly includes the exhaust pipe 231, the APC valve 244, and the pressure sensor 245. The vacuum pump 246 may be included in the exhaust system. The exhaust pipe 231 is not limited to the case where it is installed in the reaction tube 203 and may be installed in the manifold 209 in a similar manner as the nozzles 249a, 249b, and 249c.

### (Peripheral Device)

A seal cap 219 as a furnace opening lid capable of airtightly closing the lower end opening of the manifold 209 is installed below the manifold 209. The seal cap 219 is configured to make contact with the lower end of the manifold 209 from the lower side in the vertical direction. The seal cap 219 is made of a metal such as, for example, stainless steel or the like, and is formed in a disc shape. On the upper surface of the seal cap 219, there is installed an O-ring 220b as a seal member which makes contact with the lower end of the manifold 209.

On the opposite side of the seal cap 219 from the process chamber 201, there is installed a rotation mechanism 267 for rotating the boat 217. A rotating shaft 255 of the rotation mechanism 267 is connected to the boat 217 through the seal cap 219. The rotation mechanism 267 is configured to rotate the wafers 200 by rotating the boat 217. The seal cap 219 is configured to be raised and lowered in the vertical direction by a boat elevator 115 as an elevating mechanism vertically installed outside the reaction tube 203. The boat elevator 115 is configured to load and unload the boat 217 into and out of the process chamber 201 by raising and lowering the seal cap 219.

The boat elevator 115 is configured as a transfer device (transfer mechanism) for transferring the boat 217, i.e., the wafers 200, into and out of the process chamber 201. Further, below the manifold 209, a shutter 219s is installed as a furnace operation lid that can airtightly close the lower end opening of the manifold 209 while the seal cap 219 is lowered by the boat elevator 115. The shutter 219s is made of a metal such as, for example, stainless steel or the like and is formed in a disc shape. An O-ring 220c as a seal member that comes into contact with the lower end of the manifold 209 is installed on the upper surface of the shutter 219s. The opening/closing operations (the elevating operation, the rotating operation, and the like) of the shutter 219s are controlled by a shutter-opening/closing mechanism 115s.

Inside the reaction tube 203, there is installed a temperature sensor 263 as a temperature detector. By adjusting a degree of supplying electric power to the heater 207 based on the temperature information detected by the temperature sensor 263, the temperature inside the process chamber 201 becomes a desired temperature distribution. In a similar manner as the nozzles 249a and 249b, the temperature sensor 263 is installed along the inner wall of the reaction tube 203.

### (Control Device)

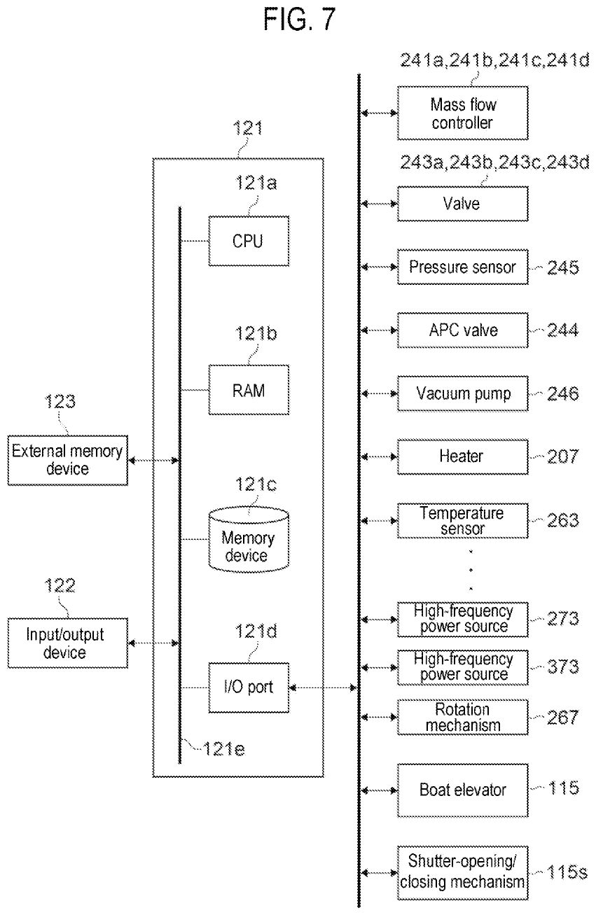

Next, a control device will be described with reference to FIG. 7. As shown in FIG. 7, the controller 121 as a control part (control device) is configured as a computer including a CPU (Central Processing Unit) 121a, a RAM (Random Access Memory) 121b, a memory device 121c, and an I/O port 121d. The RAM 121b, the memory device 121c, and the I/O port 121d are configured to exchange data with the CPU 121a via an internal bus 121e. An input/output device 122 configured as, for example, a touch panel or the like is connected to the controller 121.

The memory device 121c is composed of, for example, a flash memory, a HDD (Hard Disk Drive), a SSD (Solid State Drive), or the like. In the memory device 121c, there are readably stored a control program for controlling the operation of the substrate processing apparatus, a process recipe in which procedures and conditions of a film-forming process to be described below are written, and the like. The process recipe is a combination for causing the controller 121 to execute the respective procedures in below-described various processes (film-forming process) so as to obtain a predetermined result. The process recipe functions as a program. Hereinafter, the process recipe, the control program, and the like are collectively and simply referred to as a program. Furthermore, the process recipe is also simply referred to as a recipe. When the term “program” is used herein, it may mean a case of including only the recipe, a case of including only the control program, or a case of including both the recipe and the control program. The RAM 121b is configured as a memory area (work area) in which programs, data, and the like read by the CPU 121a are temporarily held.

The I/O port 121d is connected to the MFCs 241a to 241d, the valves 243a to 243d, the pressure sensor 245, the APC valve 244, the vacuum pump 246, the heater 207, the temperature sensor 263, the rotation mechanism 267, the boat elevator 115, the shutter-opening/closing mechanism 115s, the high-frequency power sources 273 and 373, and the like.

The CPU 121a is configured to read and execute the control program from the memory device 121c and to read the recipe from the memory device 121c in response to an input of an operation command from the input/output device 122 or the like. The CPU 121a is configured to, according to the contents of the recipe thus read, control the operation of the rotation mechanism 267, the flow rate adjustment operation of various gases by the MFCs 241a to 241d, the opening/closing operations of the valves 243a to 243d, the opening/closing operation of the APC valve 244, the pressure regulation operation by the APC valve 244 based on the pressure sensor 245, the start and stop of the vacuum pump 246, the temperature adjustment operation of the heater 207 based on the temperature sensor 263, the forward/reverse rotation, the rotation angle and the rotation speed adjustment operation of the boat 217 by the rotation mechanism 267, the raising and lowering operation of the boat 217 by the boat elevator 115, the opening/closing operation of the shutter 219s by the shutter-opening/closing mechanism 115s, the power supply of the high-frequency power sources 273 and 373, and the like.

The controller 121 may be configured by installing, in the computer, the above-described program stored in an external memory device 123 (e.g., a magnetic disk such as a hard disk or the like, an optical disk such as a CD or the like, a magneto-optical disk such as a MO or the like, and a semiconductor memory such as a USB memory, a SSD, or the like). The memory device 121c and the external memory device 123 are configured as a non-transitory computer readable recording medium. Hereinafter, the memory device 121c and the external memory device 123 are collectively and simply referred to as a recording medium. As used herein, the term “recording medium” may include only the memory device 121c, only the external memory device 123, or both. The provision of the program to the computer may be performed by using a communication means or communication unit such as the Internet or a dedicated line without using the external memory device 123.

### (2) Substrate-Processing Process

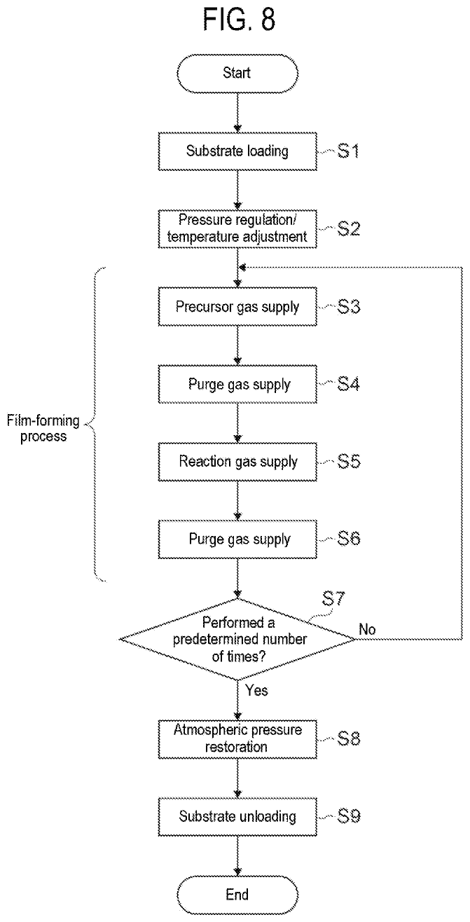

As a process of manufacturing a semiconductor device using the substrate processing apparatus described above, a process example in which a film is formed on a substrate will be described with reference to FIG. 8. In the following description, the operations of the respective parts constituting the substrate processing apparatus are controlled by the controller 121.

In the present disclosure, the sequence of the film-forming process shown in FIG. 8 may be denoted as follows for the sake of convenience. The same notation is used in the following description of modifications and other embodiments.

(precursor gas→reaction gas)×n

When the term “wafer” is used herein, it may refer to “a wafer itself” or “a stacked body of a wafer and a predetermined layer or film formed on the surface of the wafer.” When the phrase “a surface of a wafer” is used herein, it may refer to “a surface of a wafer itself” or “a surface of a predetermined layer or the like formed on a wafer.” When the expression “a predetermined layer is formed on a wafer” is used herein, it may mean that “a predetermined layer is directly formed on a surface of a wafer itself” or that “a predetermined layer is formed on a layer or the like formed on a wafer.”

When the term “substrate” is used herein, it may be synonymous with the term “wafer.”

### (Loading Step: S1)

When a plurality of wafers 200 is charged to the boat 217 (wafer charging), the shutter 219s is moved by the shutter-opening/closing mechanism 115s to open the lower end opening of the manifold 209 (shutter opening). Thereafter, as shown in FIG. 1, the boat 217 supporting the plurality of wafers 200 is lifted by the boat elevator 115 and loaded into the process chamber 201 (boat loading). In this state, the seal cap 219 seals the lower end of the manifold 209 via the O-ring 220b.

### (Pressure Regulation/Temperature Adjustment Step: S2)

The inside of the process chamber 201, i.e., the space where the wafers 200 exist, is evacuated into vacuum (evacuated into a reduced pressure) by the vacuum pump 246 so that the pressure inside the process chamber 201 becomes a desired pressure (degree of vacuum). At this time, the pressure inside the process chamber 201 is measured by the pressure sensor 245, and the APC valve 244 is feedback-controlled based on the measured pressure information. The vacuum pump 246 is always kept in operation at least until the film-forming step described below is completed.

Furthermore, the wafers 200 in the process chamber 201 are heated by the heater 207 so that the wafers 200 has a desired temperature. At this time, the degree of supplying electric power to the heater 207 is feedback-controlled based on the temperature information detected by the temperature sensor 263 so that the inside of the process chamber 201 has a desired temperature distribution. The heating of the inside of the process chamber 201 by the heater 207 is continuously performed at least until the film-forming step described below is completed.

Subsequently, the rotation mechanism 267 starts the rotation of the boat 217 and the wafers 200. The rotation of the boat 217 and the wafers 200 by the rotation mechanism 267 is continuously performed at least until the film-forming step described below is completed.

### (Film-Forming Step: S3, S4, S5, and S6)

Thereafter, a film-forming step is performed by sequentially executing steps S3, S4, S5, and S6.

### (Precursor Gas Supply Step: S3 and S4)

In step S3, a precursor gas is supplied to the wafers 200 in the process chamber 201. The valve 243a is opened to allow the precursor gas to flow into the gas supply pipe 232a. The flow rate of the precursor gas is adjusted by the MFC 241a. The precursor gas is supplied into the process chamber 201 from the gas supply holes 250a via the nozzle 249a and is exhausted from the exhaust pipe 231. At this time, the precursor gas is supplied to the wafers 200. At the same time, the valve 243c is opened to allow an inert gas to flow into the gas supply pipe 232c. The flow rate of the inert gas is adjusted by the MFC 241c. The inert gas is supplied into the process chamber 201 together with the precursor gas and is exhausted from the exhaust pipe 231.

Further, in order to prevent the precursor gas from entering the nozzle 249b, the valve 243d is opened to allow the inert gas to flow into the gas supply pipe 232d. The inert gas is supplied into the process chamber 201 via the gas supply pipe 232d and the nozzle 249b and is exhausted from the exhaust pipe 231.

Processing conditions in this step are exemplified as follows.

Processing temperature: room temperature (25 degrees C.) to 550 degrees C., preferably 400 to 500 degrees C.

Processing pressure: 1 to 4000 Pa, preferably 100 to 1000 Pa

Precursor gas supply flow rate: 0.1 to 3 slm

Precursor gas supply time: 1 to 100 seconds, preferably 1 to 50 seconds

Inert gas supply flow rate (for each gas supply pipe): 0 to 10 slm

In the present disclosure, the notation of a numerical range such as “25 to 550 degrees C.” means that the lower limit value and the upper limit value are included in the range. Therefore, for example, “25 to 550 degrees C.” means “25 degrees C. or more and 550 degrees C. or less”. The same applies to other numerical ranges. Further, in the present disclosure, the processing temperature means the temperature of the wafers 200 or the temperature in the process chamber 201, and the processing pressure means the pressure in the process chamber 201. In addition, the gas supply flow rate 0 slm means a case where the gas is not supplied. These are the same in the following description.

By supplying the precursor gas to the wafers 200 under the above-mentioned conditions, a first layer is formed on the wafer 200 (the base film on the surface). For example, when a silicon (Si)-containing gas described below is used as the precursor gas, a Si-containing layer is formed as the first layer.

After the first layer is formed, the valve 243a is closed to stop the supply of the precursor gas into the process chamber 201. At this time, the APC valve 244 is left opened, the inside of the process chamber 201 is evacuated by the vacuum pump 246, and the precursor gas unreacted or contributed to the formation of the Si-containing layer, reaction by-products, and the like remaining in the process chamber 201 are removed from the process chamber 201 (S4). In addition, the valves 243c and 243d are left opened to supply the inert gas into the process chamber 201. The inert gas acts as a purge gas.

As the precursor gas, for example, a gas containing Si and halogen, i.e., a halosilane gas may be used. Halogen includes chlorine (Cl), fluorine (F), bromine (Br), iodine (I), and the like. As the halosilane gas, for example, a chlorosilane gas containing Si and Cl may be used. More specifically, as the silane precursor gas, for example, a chlorosilane-based gas such as a monochlorosilane (SiH₃Cl, abbreviation: MCS) gas, a trichlorosilane (SiHCl₃, abbreviation: TCS) gas, a tetrachlorosilane (SiCl₄, abbreviation: STC) gas, a hexachlorodisilane (Si₂Cl₆, abbreviation: HCDS) gas, an octachlorotrisilane (Si₃Cl₈, abbreviation: OCTS) gas, or the like may be used. Further, as the silane precursor gas, a tetrafluorosilane (SiF₄) gas, a tetrabromosilane (SiBr₄) gas, a tetraiodosilane (SiI₄) gas, or the like may be used. That is, as the silane precursor gas, various halosilane-based gases such as a chlorosilane-based gas, a fluorosilane-based gas, a bromosilane-based gas, an iodosilane-based gas, and the like may be used.

As the silane precursor gas, an aminosilane-based gas such as a tetrakis(dimethylamino) silane (Si[N(CH₃)₂]₄, abbreviation: 4DMAS) gas, a tris(dimethylamino)silane (Si[N(CH₃)₂]₃H, abbreviation: 3DMAS) gas, a bis(diethylamino)silane (Si[N(C₂H₅)₂]₂H₂, abbreviation: BDEAS) gas, a bis-tertiary-butylaminosilane (SiH₂[NH(C₄H₉)]₂, abbreviation: BTBAS) gas, or the like may be used.

As the inert gas, in addition to a nitrogen (N₂) gas, it may be possible to use, for example, a rare gas such as an argon (Ar) gas, a helium (He) gas, a neon (Ne) gas, a xenon (Xe) gas, or the like. One or more of them may be used as the inert gas. This is the same in each step described below.

### (Reaction Gas Supply Step: S5 and S6)

After the precursor gas supply step is completed, a plasma-excited reaction gas is supplied to the wafers 200 in the process chamber 201 (S5).

In this step, the opening/closing control of the valves 243b to 243d is performed in the same procedure as the opening/closing control of the valves 243a, 243c, and 243d in step S3. The flow rate of the reaction gas is adjusted by the MFC 241b. The reaction gas is supplied into the buffer chamber 237 via the nozzles 249b and 249c. At this time, high-frequency power is supplied (applied) from the high-frequency power source 273 to the rod-shaped electrodes 269, 270, and 271. Further, high-frequency power is supplied (applied) from the high-frequency power source 373 to the rod-shaped electrodes 369, 370, and 371. The reaction gas supplied into each of the buffer chambers 237 is excited into a plasma state in the process chamber 201, is supplied to the wafers 200 as an active species, and is exhausted from the exhaust pipe 231.

Processing conditions in this step are exemplified as follows.

Processing temperature: room temperature (25 degrees C.) to 550 degrees C., preferably 400 to 500 degrees C.

Processing pressure: 10 to 300 Pa

Reaction gas supply flow rate: 0.1 to 10 slm

Reaction gas supply time: 10 to 100 seconds, preferably 1 to 50 seconds

Inert gas supply flow rate (for each gas supply pipe): 0 to 10 slm

RF power: 50 to 1000 W

RF frequency: 13.56 MHz or 27 MHz

By plasma-exciting and supplying the reaction gas to the wafers 200 under the above conditions, the first layer formed on the surface of each of the wafers 200 is modified by the action of the ions generated in the plasma and the electrically neutral active species, whereby the first layer is modified into a second layer.

When an oxidizing gas (oxidizing agent) such as an oxygen (O)-containing gas or the like is used as the reaction gas, an O-containing active species is generated by exciting the O-containing gas into a plasma state. The O-containing active species is supplied to the wafers 200. In this case, by the action of the O-containing active species, the first layer formed on the surface of each of the wafers 200 is subjected to an oxidizing process as a modifying process. In this case, when the first layer is, for example, a Si-containing layer, the Si-containing layer as the first layer is modified into a silicon oxide layer (SiO layer) as a second layer.

Further, when a nitride gas (nitriding agent) such as, for example, a nitrogen (N)- and hydrogen (H)-containing gas or the like is used as the reaction gas, a N- and H-containing active species is generated by exciting the N- and H-containing gas into a plasma state. The N- and H-containing active species is supplied to the wafers 200. In this case, by the action of the N- and H-containing active species, the first layer formed on the surface of each of the wafers 200 is subjected to a nitriding process as a modifying process. In this case, when the first layer is, for example, a Si-containing layer, the Si-containing layer as the first layer is modified into a silicon nitride layer (SiN layer) as a second layer.

After modifying the first layer into the second layer, the valve 243b is closed to stop the supply of the reaction gas. Further, the supply of high-frequency power to the rod-shaped electrodes 269, 271, 369, and 371 is stopped. Then, the reaction gas and the reaction by-product remaining in the process chamber 201 are removed from the process chamber 201 by the same processing procedure and processing conditions as in step S4 (S6). The reaction gas supply step may be performed by omitting this step S6.

As the reaction gas, for example, an O-containing gas or a N- and H-containing gas may be used as described above. Examples of the O-containing gas include an oxygen (O₂) gas, a nitrous oxide (N₂O) gas, a nitrogen monoxide (NO) gas, a nitrogen dioxide (NO₂) gas, an ozone (O₃) gas, a hydrogen peroxide (H₂O₂) gas, a water vapor (H₂O), an ammonium hydroxide (NH₄(OH)) gas, a carbon monoxide (CO) gas, a carbon dioxide (CO₂) gas, and the like. As the N- and H-containing gas, a hydrogen nitride-based gas such as an ammonia (NH₃) gas, a diazene (N₂H₂) gas, a hydrazine (N₂H₄) gas, a N₃H₈ gas, or the like may be used. As the reaction gas, one or more of these gases may be used.

As the inert gas, for example, various inert gases exemplified in step S4 may be used.

### (Performing a Predetermined Number of Times: S7)

By performing a cycle a predetermined number of times (n times where n is an integer of 1 or more), i.e., once or more, the cycle including performing the above-described steps S3, S4, S5, and S6 non-simultaneously, i.e., without synchronization, in this order, a film having a predetermined composition and a predetermined film thickness can be formed on each of the wafers 200. The above cycle is preferably repeated a plurality of times. That is, it is preferable that the thickness of the second layer formed per cycle is set to be smaller than a desired film thickness, and the above cycle is performed a plurality of times until the film thickness of a film formed by stacking the second layers becomes the desired film thickness. When, for example, a Si-containing layer is formed as the first layer and, for example, a SiO layer is formed as the second layer, a silicon oxide film (SiO film) is formed as the film. Further, when, for example, a Si-containing layer is formed as the first layer, and for example, a SiN layer is formed as the second layer, a silicon nitride film (SiN film) is formed as the film.

### (Atmospheric Pressure Restoration Step: S8)

When the above-described film-forming process is completed, the inert gas is supplied into the process chamber 201 from each of the gas supply pipes 232c and 232d and is exhausted from the exhaust pipe 231. As a result, the inside of the process chamber 201 is purged with the inert gas, and the reaction gas or the like remaining in the process chamber 201 is removed from the inside of the process chamber 201 (inert gas purging). Thereafter, the atmosphere in the process chamber 201 is replaced with the inert gas (inert gas replacement), and the pressure in the process chamber 201 is restored to the atmospheric pressure (atmospheric pressure restoration: S8).

### (Unloading Step: S9)

Thereafter, the seal cap 219 is lowered by the boat elevator 115 to open the lower end of the manifold 209. The processed wafers 200 supported by the boat 217 are unloaded from the lower end of the manifold 209 to the outside of the reaction tube 203 (boat unloading). After the boat is unloaded, the shutter 219s is moved and the lower end opening of the manifold 209 is sealed by the shutter 219s via the O-ring 220c (shutter closing). The processed wafers 200 are discharged out of the boat 217 after being unloaded from the reaction tube 203 (wafer discharging). After the wafer discharging, the empty boat 217 may be loaded into the process chamber 201.

In this regard, it is preferable that the pressure in the furnace at the time of substrate processing is controlled in the range of 10 Pa or more and 300 Pa or less. This is because when the pressure in the furnace is lower than 10 Pa, the mean free path of gas molecules becomes longer than the Debye length of the plasma, and the plasma that directly hits the furnace wall becomes prominent, which makes it difficult to suppress the generation of particles. Further, when the pressure in the furnace is higher than 300 Pa, the plasma generation efficiency is saturated. Therefore, the plasma generation amount is not changed even if the reaction gas is supplied. The reaction gas is wasted and the mean free path of gas molecules is shortened, thereby deteriorating the efficiency of transporting the plasma active species to the wafers.

### (3) Effect of the Present Embodiments

According to the present embodiments, one or more of the following effects may be obtained.

(a) By the different lengths of the rod-shaped electrodes 269, 369, and 371 and the rod-shaped electrode 271, the supply amount of the active species generated in the buffer chamber 237 and supplied into the process chamber 201 can be made uniform among the plurality of substrates.

(b) By adjusting the lengths of the rod-shaped electrodes 269, 271, 369, and 371, the supply amount of the active species generated in the buffer chamber 237 and supplied into the process chamber 201 can be adjusted to become uniform among the plurality of substrates.

(c) By adjusting the lengths of the rod-shaped electrodes 269, 271, 369, and 371, the supply amount of the active species generated in the buffer chamber 237 and supplied into the process chamber 201 can be adjusted to become symmetrical in the vertical direction.

(d) By adjusting the electric power supplied to the first plasma electrode unit 377 and the second plasma electrode unit 277, the supply amount of the active species supplied into the process chamber 201 can be adjusted to become symmetrical in the vertical direction.

### (Modification 1)

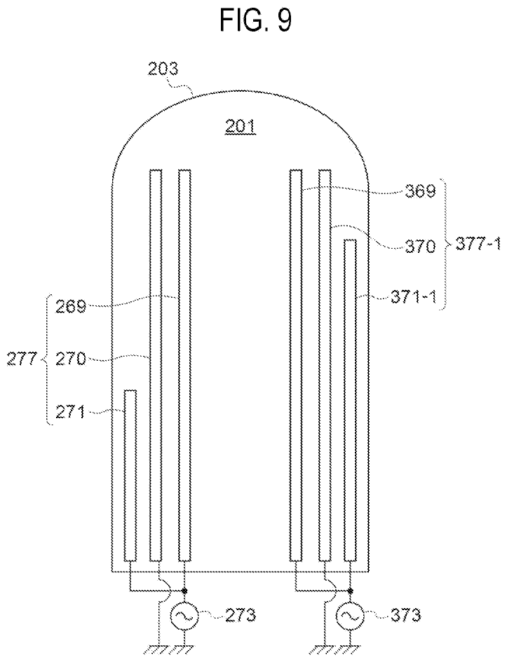

Next, modification 1 of the present embodiments will be described with reference to FIG. 9. In this modification, the parts different from the above-described embodiments will be described below, and the description of the same parts will be omitted.

In the above-described embodiments, the lengths of the rod-shaped electrodes 369, 370, and 371 of the first plasma electrode unit 377 and the rod-shaped electrodes 269 and 270 of the second plasma electrode unit 277 are substantially the same. In this modification, as shown in FIG. 9, the length of the rod-shaped electrode 371 is made different. More specifically, the length of the rod-shaped electrode 371 is made shorter than the length of the rod-shaped electrode 369, 370, 269, and 270 and longer than the length of the rod-shaped electrode 271, thereby providing a rod-shaped electrode 371-1. The first plasma electrode unit of this modification is designated by reference numeral 377-1.

By setting the length of the rod-shaped electrode 371-1 in this way, the vertical power distribution in the process chamber 201 can be adjusted by the first plasma electrode unit 377-1 alone. As a result, it is possible to adjust the bias of the supply amount of the active species supplied into the process chamber 201.

### (Modification 2)

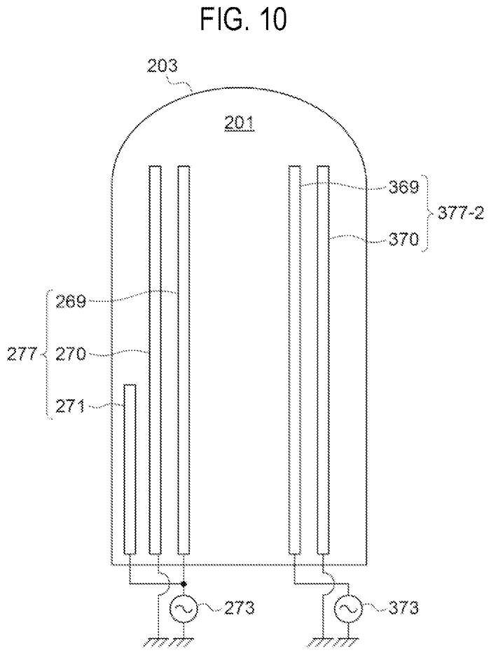

Next, modification 2 of the present embodiments will be described with reference to FIG. 10. In this modification, the parts different from the above-described embodiments will be described below, and the description of the same parts will be omitted.

In the above-described embodiments, the first plasma electrode unit 377 is installed with two application electrodes (rod-shaped electrodes 369 and 371). However, in this modification, as shown in FIG. 10, the rod-shaped electrode 371 as the second electrode is not installed. The first plasma electrode unit of this modification is designated by reference numeral 377-2.

By using one application electrode of the first plasma electrode unit 377-2 in this way, it is possible to simplify the configuration of the first plasma electrode unit 377-2. In addition, it is possible to adjust the bias of the supply amount of the active species supplied into the process chamber 201.

### (Modification 3)

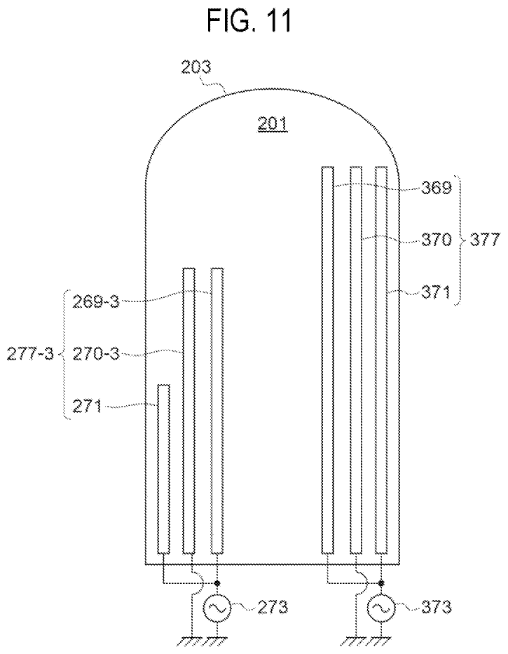

Next, modification 3 of the present embodiments will be described with reference to FIG. 11. In this modification, the parts different from the above-described embodiments will be described below, and the description of the same parts will be omitted.

In the above-described embodiments, the lengths of the rod-shaped electrodes 369, 370, and 371 of the first plasma electrode unit 377 and the rod-shaped electrodes 269 and 270 of the second plasma electrode unit 277 are substantially the same. In this modification, as shown in FIG. 11, the length of the rod-shaped electrodes 269 and 270 is different from the length of the rod-shaped electrodes 369, 370, and 371. More specifically, the lengths of the rod-shaped electrodes 269 and 270 are set to be substantially the same, and the lengths of the rod-shaped electrodes 269 and 270 are set to be shorter than the lengths of the rod-shaped electrodes 369, 370, and 371 and longer than the length of the rod-shaped electrode 271. In this modification, the rod-shaped electrodes 269 and 270 of the above-described embodiments are designated by reference numerals 269-3 and 270-3. In addition, the second plasma electrode unit of this modification is designated by reference numeral 277-3.

By setting the lengths of the rod-shaped electrodes 269-3 and 270-3 in this way, the power distribution on the lower side of the process chamber 201 can be increased. As a result, it is possible to adjust the bias of the supply amount of the active species supplied into the process chamber 201.

### (Modification 4)

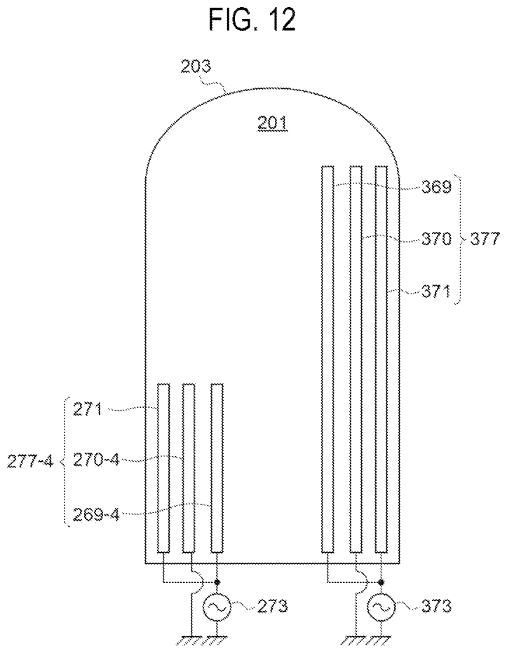

Next, modification 4 of the present embodiments will be described with reference to FIG. 12. In this modification, the parts different from the above-described embodiments will be described below, and the description of the same parts will be omitted.

In the above-described embodiments, the lengths of the rod-shaped electrodes 369, 370, and 371 of the first plasma electrode unit 377 and the rod-shaped electrodes 269 and 270 of the second plasma electrode unit 277 are substantially the same. In this modification, as shown in FIG. 12, the lengths of the rod-shaped electrodes 269 and 270 are substantially the same as the length of the rod-shaped electrode 271. That is, the lengths of the rod-shaped electrodes 269, 270, and 271 are set to be substantially the same, and the lengths of these rod-shaped electrodes 269, 270, and 271 are set to be shorter than the lengths of the rod-shaped electrodes 369, 370, and 371. In this modification, the rod-shaped electrodes 269 and 270 of the above-described embodiments are designated by reference numerals 269-4 and 270-4. Further, the second plasma electrode unit of this modification is designated by reference numeral 277-4.

By setting the lengths of the rod-shaped electrodes 269-4 and 270-4 in this way, it is possible to adjust the bias of the supply amount of the active species supplied into the process chamber 201.

### (Modification 5)

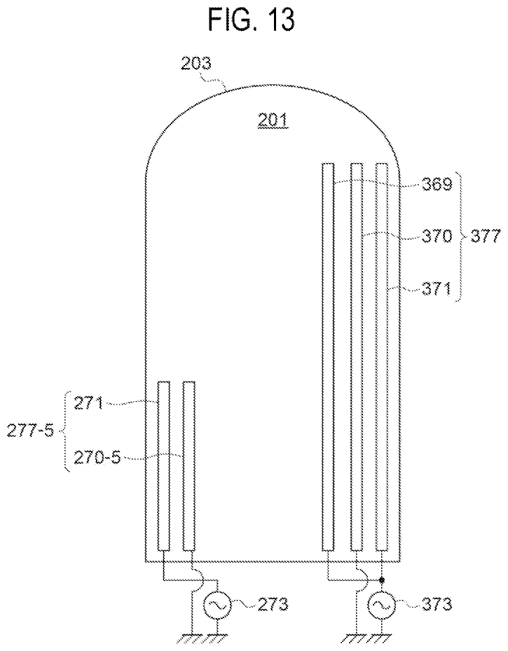

Next, modification 5 of the present embodiments will be described with reference to FIG. 13. In this modification, the parts different from the above-described embodiments will be described below, and the description of the same parts will be omitted.

In the above-described embodiments, the second plasma electrode unit 277 is installed with two application electrodes (rod-shaped electrodes 269 and 271). However, in this modification, as shown in FIG. 13, the rod-shaped electrode 269 is not installed. Further, the length of the rod-shaped electrode 270 is set to be substantially the same as the length of the rod-shaped electrode 271. The rod-shaped electrode 270 of this modification is designated by reference numeral 270-5, and the second plasma electrode unit is designated by reference numeral 277-5.

By using one application electrode of the second plasma electrode unit 277-5 in this way, it is possible to simplify the configuration of the second plasma electrode unit 277-5. In addition, it is possible to adjust the bias of the supply amount of the active species supplied into the process chamber 201.

### (Modification 6)

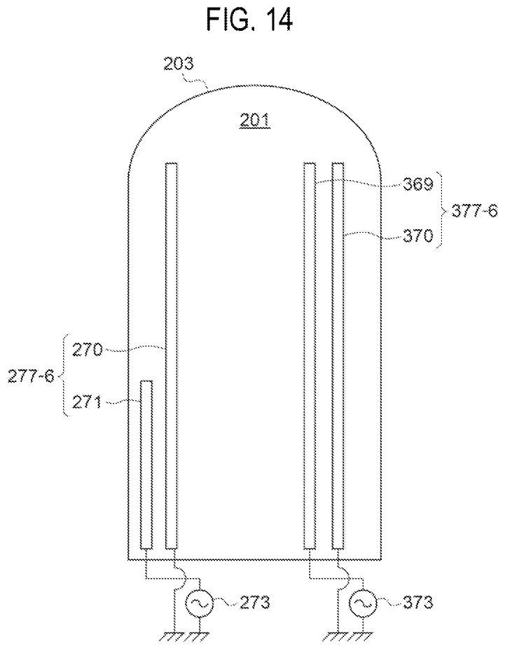

Next, modification 6 of the present embodiments will be described with reference to FIG. 14. In this modification, the parts different from the above-described embodiments will be described below, and the description of the same parts will be omitted.

In the above-described embodiments, the first plasma electrode unit 377 is installed with two application electrodes (rod-shaped electrodes 369 and 371), and the second plasma electrode unit 277 is installed with two application electrodes (rod-shaped electrodes 269 and 271). In this modification, as shown in FIG. 14, the rod-shaped electrodes 269 and 369 are not installed. The first plasma electrode unit of this modification is designated by reference numeral 377-6, and the second plasma electrode unit is designated by reference numeral 277-6.

By using one application electrode in each of the first plasma electrode unit 377-6 and the second plasma electrode unit 277-6 in this way, it is possible to simplify the configurations of the first plasma electrode unit 377-6 and the second plasma electrode unit 277-6. In addition, it is possible to adjust the bias of the supply amount of the active species supplied into the process chamber 201.

### (Modification 7)

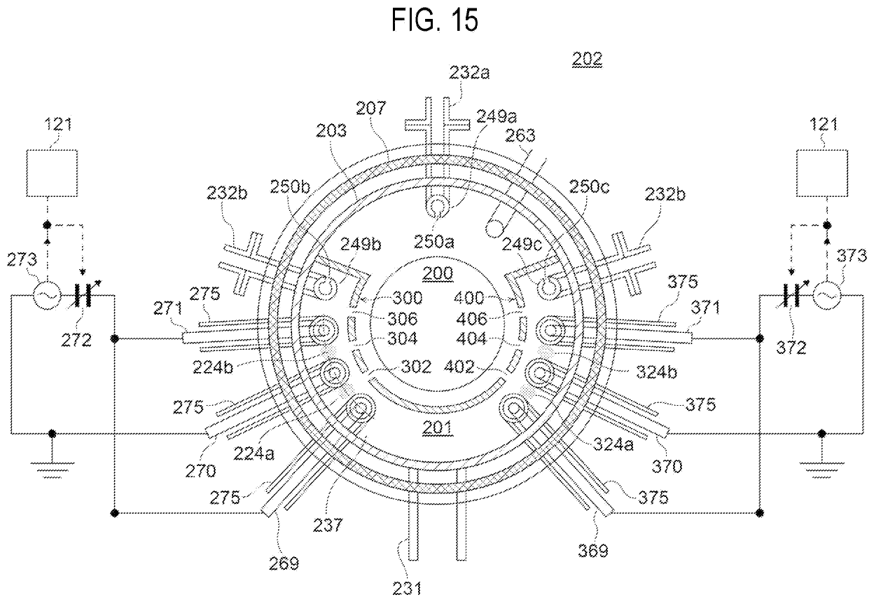

Next, modification 7 of the present embodiments will be described with reference to FIG. 15. In this modification, the parts different from the above-described embodiments will be described below, and the description of the same parts will be omitted.

In the above-described embodiments, the separately partitioned buffer chambers 237 are formed in the respective buffer structures 300 and 400. In this modification, as shown in FIG. 15, the radial walls of the buffer structures 300 and 400 facing each other across the exhaust pipe 231 are removed, and the circumferential walls of the removed portions extend to form an integrated body, whereby the buffer chambers 237 are integrated into one chamber.

In this way, the first plasma electrode unit 377 and the second plasma electrode unit 277 can be stored in the same buffer structure.

### (Modification 8)

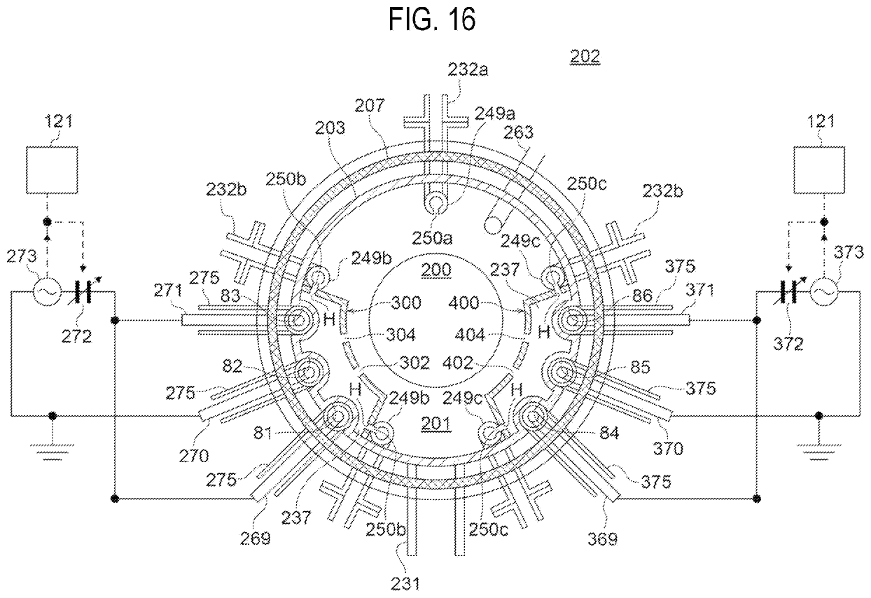

Next, modification 8 of the present embodiments will be described with reference to FIG. 16. In this modification, the parts different from the above-described embodiments will be described below, and the description of the same parts will be omitted.

In the above-described embodiments, the first plasma electrode unit 377 and the second plasma electrode unit 277 are installed in the buffer chambers 237 of the respective buffer structures 300 and 400 formed inside the reaction tube 203. In this modification, as shown in FIG. 16, the first plasma electrode unit 377 and the second plasma electrode unit 277 are installed outside the reaction tube 203.

On the wall surface of the portion of the reaction tube 203 that constitutes the buffer structure 300, three vertically extending recesses 81, 82, and 83 formed by recessing the outer surface of the reaction tube 203 are installed at equal intervals. Similarly, three recesses 84, 85, and 86 are installed at equal intervals on the wall surface of the portion of the reaction tube 203 that constitutes the buffer structure 400.

The rod-shaped electrode 269 and the electrode protection tube 275 surrounding the rod-shaped electrode 269 are arranged along the recess 81, the rod-shaped electrode 270 and the electrode protection tube 275 surrounding the rod-shaped electrode 270 are arranged along the recess 82, and the rod-shaped electrode 271 and the electrode protection tube 275 surrounding the rod-shaped electrode 271 are arranged along the recess 83. Further, the rod-shaped electrode 369 and the electrode protection tube 375 surrounding the rod-shaped electrode 369 are arranged along the recess 84, the rod-shaped electrode 370 and the electrode protection tube 375 surrounding the rod-shaped electrode 370 are arranged along the recess 85, and the rod-shaped electrode 371 and the electrode protection tube 375 surrounding the rod-shaped electrode 371 are arranged along the recess 86.

Each of the nozzles 249b and 249c for supplying the reaction gas is branched into two portions and is arranged outside the buffer chamber 237 to extend along the wall surface that constitutes the buffer structures 300 and 400 formed in the radial direction of the reaction tube 203. The gas supply holes 250b and 250c of the nozzle 249b and the nozzle 249c are opened so as to face the holes H formed in the adjacent wall surfaces of the buffer structures 300 and 400, respectively.

### (Modification 9)

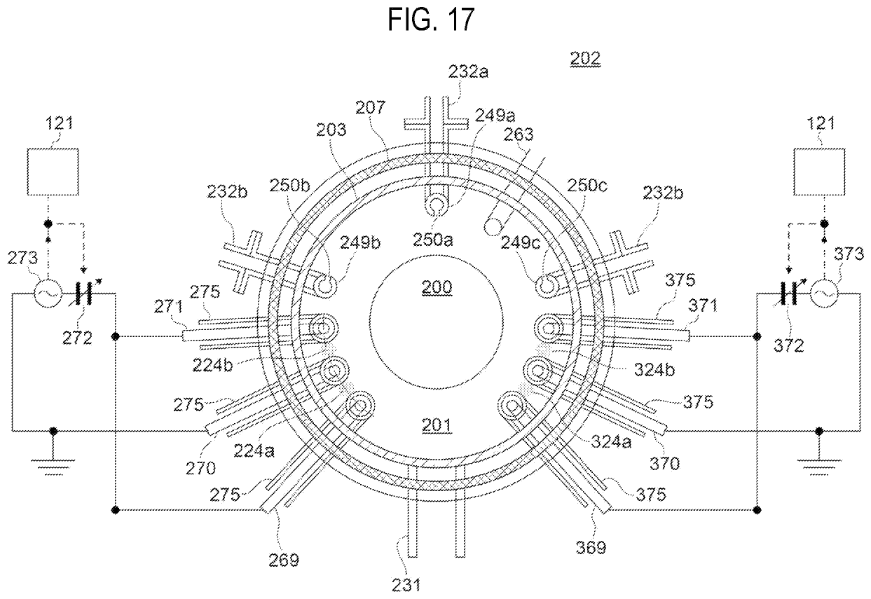

Next, modification 9 of the present embodiments will be described with reference to FIG. 17. In this modification, the parts different from the above-described embodiments will be described below, and the description of the same parts will be omitted.

In the above-described embodiments, the first plasma electrode unit 377 and the second plasma electrode unit 277 are installed in the buffer chambers 237 of the respective buffer structures 300 and 400 formed inside the reaction tube 203. In this modification, as shown in FIG. 17, the walls constituting the buffer structures 300 and 400 are not installed. The first plasma electrode unit 377 and the second plasma electrode unit 277 are installed in the process chamber 201 without being partitioned.

### (Modification 10)

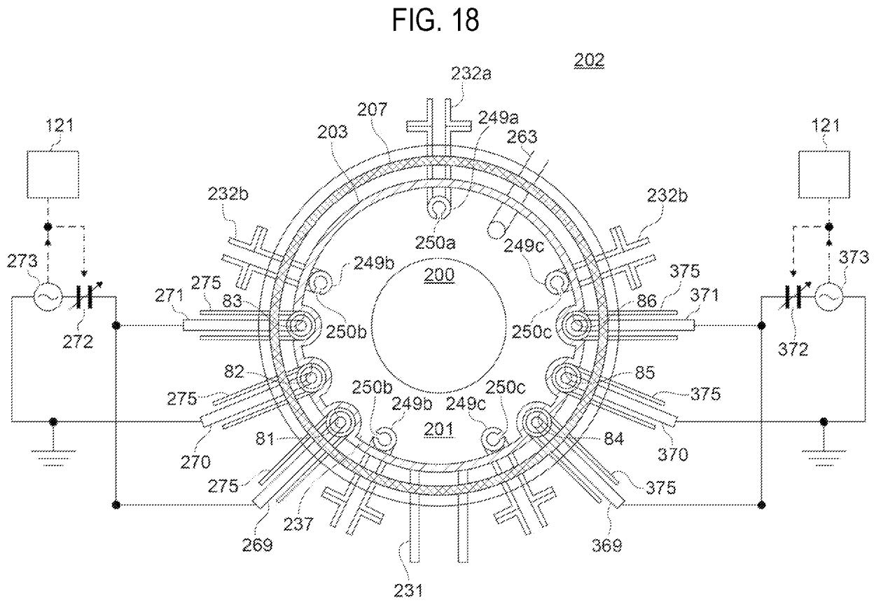

Next, modification 10 of the present embodiments will be described with reference to FIG. 18. In this modification, the parts different from the above-described embodiments will be described below, and the description of the same parts will be omitted.

In the above-mentioned modification 8, the first plasma electrode unit 377 and the second plasma electrode unit 277 are installed at positions corresponding to the buffer structures 300 and 400 outside the reaction tube 203. However, in this modification, as shown in FIG. 18, the buffer structures 300 and 400 are not installed. That is, it is a configuration in which the buffer structures 300 and 400 are removed from modification 8.

### (Modification 11)

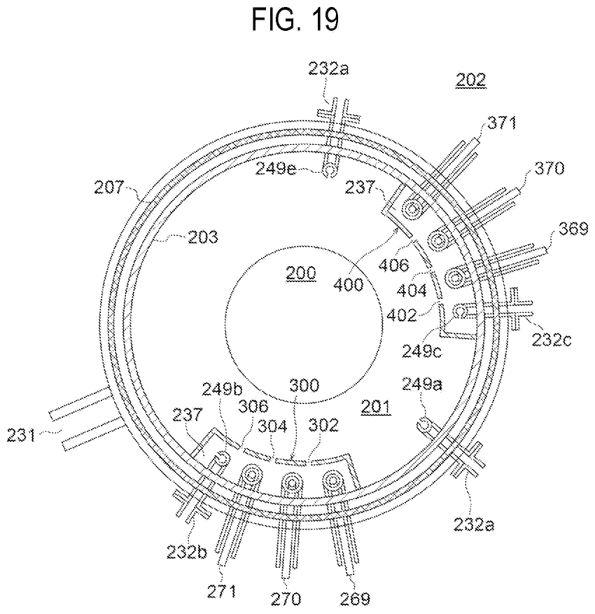

Next, modification 11 of the present embodiments will be described with reference to FIG. 19. In this modification, the parts different from the above-described embodiments will be described below, and the description of the same parts will be omitted.

In the above-described embodiments, the buffer structure 300 and the buffer structure 400 are installed line-symmetrically with respect to a straight line passing through the exhaust pipe 231 and the center of the reaction tube 203 with the exhaust pipe 231 interposed therebetween. In this modification, the buffer structure 300 and the buffer structure 400 are arranged asymmetrically with respect to a straight line passing through the center of the exhaust pipe 231 and the reaction tube 203 with the exhaust pipe 231 interposed therebetween. More specifically, the buffer structure 400 is arranged at a position facing the exhaust pipe 231, and the gas supply pipe 232a branched into two portions is arranged on both outer sides of the buffer structure 400 in the circumferential direction. Further, the buffer structure 300 is arranged between the gas supply pipe 232a and the exhaust pipe 231 in the circumferential direction. The second plasma electrode unit 277 is arranged in the buffer structure 300, and the first plasma electrode unit 377 is arranged in the buffer structure 400.

In this modification, the first plasma electrode unit 377 having a large generation amount of active species is arranged at a position facing the exhaust pipe 231, and the second plasma electrode unit 277 having a small generation amount of active species is installed on the lateral side of the exhaust pipe 231, which makes it possible to adjust the bias of the supply amount of the active species supplied into the process chamber 201.

The circumferential positions of the first plasma electrode unit 377 and the second plasma electrode unit 277 in the process chamber 201 can be set arbitrarily in consideration of the amount of active species generated by each plasma electrode unit, the distribution of the amount of active species in the extension direction of the electrodes, and the like, so that the distribution of the processing amount (e.g., the film thickness distribution) in the substrate plane of the process using the active species and/or the distribution of the processing amount between the substrates become a desired distribution (e.g., a uniform distribution).

### (Modification 12)

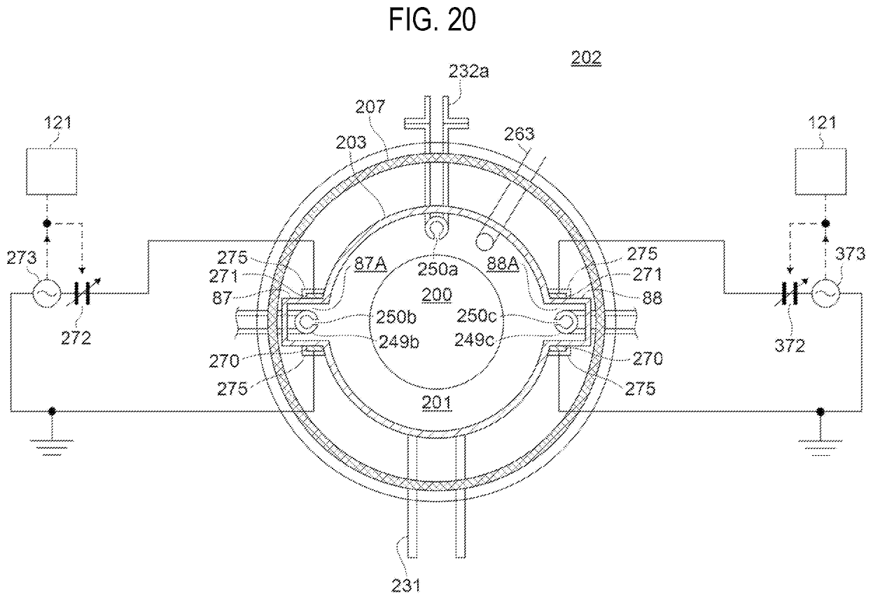

Next, modification 12 of the present embodiments will be described with reference to FIG. 20. In this modification, the parts different from the above-described embodiments will be described below, and the description of the same parts will be omitted.

In the above-described embodiments, the first plasma electrode unit 377 and the second plasma electrode unit 277 are installed in the buffer chambers 237 of the respective buffer structures 300 and 400 formed in the reaction tube 203. In this modification, as shown in FIG. 20, the first plasma electrode unit 377 and the second plasma electrode unit 277 are installed outside the reaction tube 203.

Protrusions 87 and 88 protruding radially outward of the reaction tube 203 and extending in the vertical direction are formed on the opposite side walls of the reaction tube 203 facing each other across the exhaust pipe 231. Spaces 87A and 88A are formed inside the respective protrusions 87 and 88. The nozzle 249b is arranged in the space 87A and the nozzle 249c is arranged in the space 88A. The gas supply holes 250b and 250c of the nozzle 249b and the nozzle 249c are opened so as to face radially inward of the reaction tube 203.

In this modification, similar to modification 6, the rod-shaped electrodes 269 and 369 are not installed. The first plasma electrode unit 377 of this modification includes rod-shaped electrodes 370 and 371 and electrode protection tubes 275, and the second plasma electrode unit 277 includes rod-shaped electrodes 270 and 271 and electrode protection tubes 275. The rod-shaped electrodes 370 and 371 are arranged so as to sandwich the protrusion 88 in the circumferential direction, and the rod-shaped electrodes 270 and 271 are arranged so as to sandwich the protrusion 87 in the circumferential direction. In this modification, the cross-sectional shape of the rod-shaped electrodes 270, 271, 370, and 371 is rectangular.

The rod-shaped electrodes 270, 271, 370, and 371 are arranged so that the long side of the rectangular cross section extends along the protrusions 87 and 88 and the short side thereof extends along the outer circumferential surface of the reaction tube 203. The electrode protection tubes 275 are configured to cover the portions of the rod-shaped electrodes 270, 271, 370, and 371 which are not surrounded by the wall of the reaction tube 203.

The embodiments of the present disclosure have been specifically described above. However, the present disclosure is not limited to the above-described embodiments, and various changes may be made without departing from the gist thereof.

Further, for example, in the above-described embodiments, there has been described the example in which the reactant is supplied after supplying the precursor. The present disclosure is not limited to such embodiments. The supply order of the precursor and the reactant may be reversed. That is, the precursor may be supplied after supplying the reactant. By changing the supply order, it is possible to change the film quality and composition ratio of the formed film.

The present disclosure may be suitably applied to not only the case where the SiO film or the SiN film is formed on the wafer 200, but also a case where a Si-based oxide film such as a silicon oxycarbide film (SiOC film), a silicon oxycarbonitride film (SiOCN film), a silicon oxynitride film (SiON film), or the like is formed on the wafer 200.

For example, instead of or in addition to the above-mentioned gases, a nitrogen (N)-containing gas such as an ammonia (NH₃) gas, a diazene (N₂H₂) gas, a hydrazine (N₂H₄) gas, a N₃H₈ gas, or the like, a carbon (C)-containing gas such as a propylene (C₃H₆) gas or the like, and a boron (B)-containing gas such as a boron trichloride (BCl₃) gas or the like may be used to form, for example, a SiN film, a SiON film, a SiOCN film, a SiOC film, a SiCN film, a SiBN film, a SiBCN film, and a BCN film. The supply order of the respective gases may be changed as appropriate. Even when these film formations are performed, film formation may be performed under the same processing conditions as those in the above-described embodiments, and the same effects as those in the above-described embodiments may be obtained. In these cases, the above-described reaction gas may be used as the oxidizing agent.

Further, the present disclosure may be suitably applied to a case where a metal-based oxide film or a metal-based nitride film containing a metal element such as titanium (Ti), zirconium (Zr), hafnium (Hf), tantalum (Ta), niobium (Nb), aluminum (Al), molybdenum (Mo), tungsten (W), or the like is formed on the wafer 200. That is, the present disclosure may be suitably applied to a case where a TiO film, a TiOC film, a TiOCN film, a TiON film, a TiN film, a TiSiN film, a TiBN film, a TiBCN film, a ZrO film, a ZrOC film, a ZrOCN film, a ZrON film, a ZrN film, a ZrSiN film, a ZrBN film, a ZrBCN film, a HfO film, a HfOC film, a HfOCN film, a HfON film, a HfN film, a HfSiN film, a HfBN film, a HfBCN film, a TaO film, a TaOC film, a TaOCN film, a TaON film, a TaN film, a TaSiN film, a TaBN film, a TaBCN film, a NbO film, a NbOC film, a NbOCN film, a NbON film, a NbN film, a NbSiN film, a NbBN film, a NbBCN film, an AlO film, an AlOC film, an AlOCN film, an AlON film, an AlN film, an AlSiN film, an AlBN film, an AlBCN film, a MoO film, a MoOC film, a MoOCN film, a MoON film, a MoN film, a MoSiN film, a MoBN film, a MoBCN film, a WO film, a WOC film, a WOCN film, a WON film, a WN film, a WSiN film, a WBN film, a WBCN film, or the like is formed on the wafer 200.

In these cases, as the precursor gas, it may be possible to use, for example, a tetrakis (dimethylamino) titanium (Ti[N(CH₃)₂]₄, abbreviation: TDMAT) gas, a tetrakis (ethylmethylamino) hafnium (Hf[N(C₂H₅)(CH₃)]₄, abbreviation: TEMAH) gas, a tetrakis (ethylmethylamino) zirconium (Zr[N(C₂H₅)(CH₃)]₄, abbreviation: TEMAZ) gas, a trimethylaluminum (Al(CH₃)₃, abbreviation: TMA) gas, a titanium tetrachloride (TiCl₄) gas, a hafnium tetrachloride (HfCl₄) gas, and the like.

That is, the present disclosure may be suitably applied to a case of forming a metalloid-based film containing a metalloid element or a metal-based film containing a metal element. The processing procedure and processing conditions for these film-forming processes may be the same as those for the film-forming processes of the above-described embodiments and modifications. In these cases, the same effects as those of the above-described embodiments may be obtained.

It is preferable that the recipe used for the film-forming process are prepared separately according to the processing contents and are stored in the memory device 121c via an electric communication line or an external memory device 123. When starting various processes, it is preferable that the CPU 121a properly selects an appropriate recipe from a plurality of recipes stored in the memory device 121c according to the contents of the process. This makes it possible to form thin films of various film types, composition ratios, film qualities, and film thicknesses in a general manner and with high reproducibility in a single substrate processing apparatus. In addition, the burden on an operator can be reduced, and various processes can be quickly started while avoiding operation errors.

The above-described recipes are not limited to the newly-prepared ones, but may be prepared by, for example, changing the existing recipes already installed in the substrate processing apparatus. In the case of changing the recipes, the recipes after the change may be installed in the substrate processing apparatus via an electric communication line or a recording medium in which the recipes are recorded. In addition, the input/output device 122 included in the existing substrate processing apparatus may be operated to directly change the existing recipes already installed in the substrate processing apparatus.

According to the present disclosure in some embodiments, it is possible to provide a technique capable of reducing variations in processing amount for a plurality of substrates.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a process chamber configured to process a substrate;
a gas supplier configured to supply a gas into the process chamber;
a first plasma electrode unit including a first reference electrode applied with a reference potential and at least one selected from the group of a first application electrode and a second application electrode applied with high-frequency power, the first plasma electrode unit configured to plasma-excite the gas; and
a second plasma electrode unit including a second reference electrode applied with a reference potential and a third application electrode applied with high-frequency power, the third application electrode having a length different from a length of the first application electrode or the second application electrode, and the second plasma electrode unit configured to plasma-excite the gas.

2. The substrate processing apparatus of claim 1, wherein the second plasma electrode unit further includes a fourth application electrode applied with high-frequency power and having a length different from the length of the third application electrode.

3. The substrate processing apparatus of claim 2, wherein the fourth application electrode has the same length as the second reference electrode.

4. The substrate processing apparatus of claim 1, wherein the third application electrode is shorter than the first application electrode or the second application electrode.

5. The substrate processing apparatus of claim 2, wherein the third application electrode is shorter than the fourth application electrode.

6. The substrate processing apparatus of claim 1, wherein the third application electrode is shorter than the second reference electrode.

7. The substrate processing apparatus of claim 2, wherein the fourth application electrode has the same length as at least one selected from the group of the first application electrode and the second application electrode.

8. The substrate processing apparatus of claim 1, wherein the first application electrode has the same length as the first reference electrode.

9. The substrate processing apparatus of claim 1, wherein the first plasma electrode unit includes the first application electrode and the second application electrode.

10. The substrate processing apparatus of claim 9, wherein the second application electrode has the same length as the first application electrode.

11. The substrate processing apparatus of claim 1, wherein the second application electrode is shorter than the first application electrode.

12. The substrate processing apparatus of claim 2, wherein the fourth application electrode has the length different from the length of the first application electrode or the second application electrode.

13. The substrate processing apparatus of claim 12, wherein the fourth application electrode is shorter than the first application electrode or the second application electrode.

14. The substrate processing apparatus of claim 1, wherein the second plasma electrode unit further includes a fourth application electrode applied with high-frequency power and having the same length as the third application electrode.

15. The substrate processing apparatus of claim 1, further comprising:
a first high-frequency power source configured to supply high-frequency power to the at least one selected from the group of the first application electrode and the second application electrode; and
a second high-frequency power source, which is different from the first high-frequency power source, configured to supply high-frequency power to the third application electrode.

16. The substrate processing apparatus of claim 1, further comprising:
a first high-frequency power source configured to supply high-frequency power to the first plasma electrode unit; and
a second high-frequency power source, which is different from the first high-frequency power source, configured to supply high-frequency power to the second plasma electrode unit.

17. The substrate processing apparatus of claim 16, further comprising:
a controller configured to be capable of controlling the first high-frequency power source and the second high-frequency power source so that a total distribution including a distribution of electric power applied to the first plasma electrode unit and a distribution of electric power applied to the second plasma electrode unit in an extension direction of the first plasma electrode unit and the second plasma electrode unit becomes uniform.

18. The substrate processing apparatus of claim 16, further comprising:
a controller configured to be capable of controlling the first high-frequency power source and the second high-frequency power source so that a distribution of an amount of active species generated by plasma-exciting the gas by the first plasma electrode unit and the second plasma electrode unit becomes uniform in an extension direction of the first plasma electrode unit and the second plasma electrode unit.

19. The substrate processing apparatus of claim 1, wherein the first plasma electrode unit and the second plasma electrode unit are installed outside a reaction tube including the process chamber therein.

20. A plasma generating device, comprising:
a first plasma electrode unit including a first reference electrode applied with a reference potential and at least one selected from the group of a first application electrode and a second application electrode applied with high-frequency power, the first plasma electrode unit configured to plasma-excite a gas; and
a second plasma electrode unit including a second reference electrode applied with a reference potential and a third application electrode applied with high-frequency power, the third application electrode having a length different from a length of the first application electrode or the second application electrode, and the second plasma electrode unit configured to plasma-excite the gas.

21. A method of manufacturing a semiconductor device, comprising:
loading a substrate into a process chamber of a substrate processing apparatus that includes:
the process chamber configured to process the substrate;
a first plasma electrode unit including a first reference electrode applied with a reference potential and at least one selected from the group of a first application electrode and a second application electrode applied with high-frequency power; and
a second plasma electrode unit including a second reference electrode applied with a reference potential and a third application electrode applied with high-frequency power, the third application electrode having a length different from a length of the first application electrode or the second application electrode; and
processing the substrate by plasma-exciting a gas with the first plasma electrode unit and the second plasma electrode unit to generate an active species and supplying the active species to the substrate.

22. A substrate processing method, comprising:
loading a substrate into a process chamber of a substrate processing apparatus that includes:
the process chamber configured to process the substrate;
a first plasma electrode unit including a first reference electrode applied with a reference potential and at least one selected from the group of a first application electrode and a second application electrode applied with high-frequency power; and
a second plasma electrode unit including a second reference electrode applied with a reference potential and a third application electrode applied with high-frequency power, the third application electrode having a length different from a length of the first application electrode or the second application electrode; and
processing the substrate by plasma-exciting a gas with the first plasma electrode unit and the second plasma electrode unit to generate an active species and supplying the active species to the substrate.
